(19) United States
(12) Patent Application Publication
(10) Pub. No.: US 2026/0344209 A1
(43) Pub. Date: Oct. 29, 2026

(54) DISPLAY PANEL, DISPLAY DEVICE AND DRIVING METHOD

(71) Applicants: HEFEI BOE JOINT TECHNOLOGY CO., LTD., Hefei, Anhui (CN); BOE TECHNOLOGY GROUP CO., LTD., Beijing (CN); BEIJING BOE TECHNOLOGY DEVELOPMENT CO., LTD., Beijing (CN)

(72) Inventors: Can YUAN, Beijing (CN); Yongqian LI, Beijing (CN)

(73) Assignees: HEFEI BOE JOINT TECHNOLOGY CO., LTD., Hefei, Anhui (CN); BOE TECHNOLOGY GROUP CO., LTD., Beijing (CN); BEIJING BOE TECHNOLOGY DEVELOPMENT CO., LTD., Beijing (CN)

(21) Appl. No.: 18/840,285

(22) PCT Filed: Nov. 30, 2023
(86) PCT No.: PCT/CN2023/135376

§ 371 Date: Aug. 21, 2024

(51) Int. Cl. H10K 59/131; G09G 3/3233; H10K 59/121; H10K 59/122; H10K 59/123; H10K 102/00

(52) U.S. Cl. CPC H10K 59/131; G09G 3/3233; H10K 59/1213; H10K 59/1216; H10K 59/122; H10K 59/123; G09G 2300/0819; G09G 2300/0842; G09G 2310/08; H10K 2102/351

(57) ABSTRACT

A display panel, a display device and a driving method are provided. The display panel includes a base substrate, a plurality of pixel opening areas arranged on the base substrate, at least one planarization layer and at least two conductive layers stacked on the base substrate, wherein one planarization layer is arranged between adjacent conductive layers, and the planarization layer has a first type of via hole and a second type of via hole; an orthographic projection of the first type of via hole on the base substrate does not overlap an orthographic projection of the pixel opening area on the base substrate; an orthographic projection of the second type of via hole on the base substrate does not overlap the orthographic projection of the pixel opening area on the base substrate.

### TECHNICAL FIELD

The present disclosure relates to the field of display technology, in particular to a display panel, a display device and a driving method.

### BACKGROUND

In the related art, a printing process can be used to manufacture light emitting devices. This printing process requires a highly flat substrate. If the base substrate is uneven or not flat enough, it will affect the light color and electrical characteristics of the light emitting device. The result is that the light color of the light emitting device is deviated, and the efficiency, life and other characteristics of the light emitting device will also be greatly deteriorated.

### SUMMARY

In one aspect, the present disclosure provides in some embodiments a display panel, including a base substrate, a plurality of pixel opening areas arranged on the base substrate, at least one planarization layer and at least two conductive layers stacked on the base substrate, wherein one planarization layer is arranged between adjacent conductive layers, and the planarization layer has a first type of via hole and a second type of via hole; the display panel includes a signal line for transmitting a reference voltage signal, and a signal line for transmitting a power supply voltage signal; the signal line for transmitting the reference voltage signal includes a first signal line and a second signal line; the first signal line is electrically connected to the second signal line through the first type of via hole; the signal line for transmitting the power supply voltage signal includes a third signal line and a fourth signal line, and the third signal line is electrically connected to the fourth signal line through the second type of via hole; an orthographic projection of the first type of via hole on the base substrate does not overlap an orthographic projection of the pixel opening area on the base substrate; an orthographic projection of the second type of via hole on the base substrate does not overlap the orthographic projection of the pixel opening area on the base substrate.

Optionally, the display panel comprises a first conductive layer, a second conductive layer, and a first planarization layer; the first conductive layer, the first planarization layer, and the second conductive layer are arranged in sequence along a direction away from the base substrate; the first signal line is a first reference signal line, and the second signal line is a first reference connection line; the first type of via hole includes a first via hole; the first conductive layer includes the first reference signal line, and the second conductive layer includes the first reference connection line; the first planarization layer has the first via hole; the first reference signal line is electrically connected to the first reference connection line through the first via hole.

Optionally, the display panel further comprises a third conductive layer; the first conductive layer includes a second reference signal line; the third conductive layer includes a second reference connection line; the second reference signal line is electrically connected to the second reference connection line; the third conductive layer is provided between the base substrate and the first conductive layer; the first reference connection line and the second reference connection line both extend along a first direction; orthographic projections of two second reference connection lines on the base substrate are arranged on opposite sides of an orthographic projection of the first reference connection line on the base substrate.

Optionally, the display panel comprises a first conductive layer, a second conductive layer, and a first planarization layer; the first conductive layer, the first planarization layer and the second conductive layer are arranged in sequence along a direction away from the base substrate; the third signal line is a first voltage line, and the fourth signal line is a first voltage connection line; the second type of via hole includes a second via hole; the first conductive layer includes the first voltage line, and the second conductive layer includes the first voltage connection line; the first planarization layer has the second via hole; the first voltage line is electrically connected to the first voltage connection line through the second via hole.

Optionally, the planarization layer has a third type of via hole; the display panel includes a plurality of sub-pixels arranged on the base substrate; the sub-pixels include a light emitting element, a storage capacitor, and a plurality of transistors; the sub-pixel includes a plurality of conductive portions, the plurality of conductive portions include an anode of the light emitting element, electrode plates of the storage capacitor, and an electrode of the transistor; some of the plurality of conductive portions are electrically connected through the third type of via hole; an orthographic projection of the third type of via hole on the base substrate does not overlap the orthographic projection of the pixel opening area on the base substrate.

Optionally, the planarization layer has a fourth type of via hole; the display panel includes a plurality of data lines and a plurality of sub-pixels arranged on the base substrate; some electrodes of some transistors in the sub-pixels are electrically connected to the data lines through the fourth type of via hole; an orthographic projection of the fourth type of via hole on the base substrate does not overlap the orthographic projection of the pixel opening area on the base substrate.

Optionally, the transistor in the sub-pixel comprises a first reset transistor; the third type of via hole comprises a third via hole and a fourth via hole; the display panel also includes a semiconductor layer, a first conductive layer, a first planarization layer, a second conductive layer, a second planarization layer and a fourth conductive layer arranged in sequence in a direction away from the base substrate; the semiconductor layer includes a first electrode of the first reset transistor, and the fourth conductive layer includes an anode of the light emitting element; the first planarization layer has the third via hole, and the second planarization layer has the fourth via hole; the first electrode of the first reset transistor is electrically connected to the anode of the light emitting element through the third via hole and the fourth via hole.

Optionally, the third type of via holes includes a fifth via hole and a sixth via hole; the display panel further includes a fifth conductive layer, a first insulating layer, a first conductive layer, a first planarization layer, a second conductive layer, a second planarization layer and a fourth conductive layer arranged in sequence along a direction away from the base substrate; the fourth conductive layer includes the anode of the light emitting element; the fifth conductive layer includes the first electrode plate of the storage capacitor; the first planarization layer has the fifth via hole, and the second planarization layer has the sixth via hole; the anode of the light emitting element is electrically connected to the first electrode plate of the storage capacitor through the sixth via hole, the fifth via hole, and a via hole penetrating the first insulating layer.

Optionally, the transistor in the sub-pixel includes a data writing-in transistor; the fourth type of via hole includes a seventh via; the display panel further includes a semiconductor layer, a first conductive layer, a first planarization layer, and a second conductive layer arranged in sequence along a direction away from the base substrate; the semiconductor layer includes the first electrode of the data writing-in transistor, and the second conductive layer includes the data line; the first planarization layer has the seventh via hole, and the first electrode of the data writing-in transistor is electrically connected to the data line through the seventh via hole.

Optionally, the transistor in the sub-pixel includes a first reset transistor; the third type of via hole includes a third via hole, a fourth via hole and an eighth via hole; the display panel further includes a semiconductor layer, a first conductive layer, a first planarization layer, a second conductive layer, a second planarization layer, a fourth conductive layer, a third planarization layer and a sixth conductive layer arranged in sequence in a direction away from the base substrate; the semiconductor layer includes the first electrode of the first reset transistor, and the sixth conductive layer includes the anode of the light emitting element; the first planarization layer has the third via hole, the second planarization layer has the fourth via hole, and the third planarization layer has the eighth via hole; the first electrode of the first reset transistor is electrically connected to the anode of the light emitting element through the third via hole, the fourth via hole and the eighth via hole.

Optionally, the third type of via holes includes a fifth via hole, a sixth via hole and a ninth via hole; the display panel further includes a fifth conductive layer, a first insulating layer, a first conductive layer, a first planarization layer, a second conductive layer, a second planarization layer, a fourth conductive layer, a third planarization layer and a sixth conductive layer arranged in sequence in a direction away from the base substrate; the sixth conductive layer includes the anode of the light emitting element, and the fifth conductive layer includes the first electrode plate of the storage capacitor; the first planarization layer has the fifth via hole, the second planarization layer has the sixth via hole, and the third planarization layer has the ninth via hole; the anode of the light emitting element is electrically connected to the first electrode plate of the storage capacitor through the ninth via hole, the sixth via hole, the fifth via hole, and the via hole penetrating the first insulating layer.

Optionally, the plurality of sub-pixels are divided into a plurality of pixel units arranged in an array; the pixel unit includes a plurality of sub-pixels arranged along a second direction; the first direction intersects the second direction; N columns of the pixel units are arranged between two adjacent columns of the first reference connection lines; N is an integer greater than 1.

Optionally, the display panel further includes a plurality of rows and a plurality of columns of lens group arranged on a side of the pixel unit away from the base substrate; the lens group includes an odd numbered lenses; N pixel units located in a same row and arranged between two adjacent columns of first reference connection lines correspond to a same lens group.

Optionally, a pixel unit arranged between different two adjacent columns of first reference connection lines correspond to different lens groups.

Optionally, the second reference connection line is adjacent to the first reference connection line in the second direction.

Optionally, the display panel includes a plurality of sub-pixels arranged on the base substrate; the sub-pixel includes a light emitting element; the display panel includes a second conductive layer, an anode planarization layer and a fourth conductive layer stacked in a direction away from the base substrate; the fourth conductive layer includes the anode of the light-emitting element; a thickness of the anode planarization layer is greater than a thickness of the planarization layer.

Optionally, the sub-pixels further comprise a plurality of transistors and a storage capacitor; the anode of the light emitting element is electrically connected to a part of electrodes of a part of the transistors in the plurality of transistors and/or a part of electrode plates of the storage capacitor through a fifth type of via hole in the anode planarization layer; an orthographic projection of the fifth type of via hole on the base substrate does not overlap the orthographic projection of the pixel opening area on the base substrate.

Optionally, the display panel comprises a plurality of sub-pixels arranged on the base substrate; the sub-pixel comprises a light emitting element; the light emitting element comprises a light emitting layer; the light emitting layers of the light emitting elements in a same column of sub-pixels are continuous with each other and have a same color.

Optionally, a thickness of the planarization layer is greater than a first thickness threshold, and the first thickness threshold is greater than or equal to 2.8 μm and less than or equal to 3.2 μm.

Optionally, the display panel comprises a plurality of sub-pixels arranged on the base substrate; the sub-pixel comprises a light emitting element, a storage capacitor, a first reset transistor, a data writing-in transistor and a second reset transistor; an active pattern of the second reset transistor is electrically connected to an active pattern of the data writing-in transistor through a first connection line; the active pattern of the data writing-in transistor is electrically connected to the second electrode plate of the storage capacitor through a second connection line; the anode of the light emitting element is electrically connected to the active pattern of the first reset transistor through a third connection line; the first connection line, the second connection line and the third connection line are arranged on a same layer as the active pattern.

Optionally, the display panel comprises a first pixel defining layer and a second pixel defining layer; the second pixel defining layer forms a plurality of openings arranged along the second direction, and the openings extend along the first direction; the first pixel defining layer comprises a plurality of pixel defining portions arranged along the first direction, the pixel defining portions fill a part of the openings, and the plurality of pixel defining portions define a plurality of pixel opening areas in the plurality of openings.

Optionally, the pixel defining portion comprises an integral structure extending along the second direction; or, the pixel defining portion comprises a plurality of pixel defining patterns arranged along the second direction, and at least a part of the pixel defining patterns fills in a corresponding opening.

Optionally, a maximum distance between the first pixel defining layer and the base substrate is different from a maximum distance between the second pixel defining layer and the base substrate.

In a second aspect, an embodiment of the present disclosure provides a display device comprising a display panel.

Optionally, the display panel includes a sub-pixel; the sub-pixel includes a light emitting element, an energy storage circuit, a driving circuit, a data writing-in circuit and a light emitting control circuit; a first terminal of the energy storage circuit is electrically connected to an anode of the light emitting element; a control terminal of the driving circuit is electrically connected to a second terminal of the energy storage circuit, a first terminal of the driving circuit is electrically connected to the anode of the light emitting element, and a cathode of the light emitting element is electrically connected to the second voltage line; the data writing-in circuit is electrically connected to a first scanning line, a data line and the second terminal of the energy storage circuit respectively, and is configured to write a data voltage provided by the data line into the second terminal of the energy storage circuit under the control of a first scanning signal provided by the first scanning line; the light emitting control circuit is electrically connected to the light emitting control line, a second terminal of the driving circuit and the first voltage line respectively, and is configured to control to connect the first voltage line and the second terminal of the driving circuit under the control of a light emitting control signal provided by the light emitting control line.

Optionally, the sub-pixel further comprises a first reset circuit and a second reset circuit; the second reset circuit is electrically connected to a second scanning line, a reference voltage line and a second terminal of the energy storage circuit, respectively, and is configured to write a reference voltage provided by the reference voltage line into the second terminal of the energy storage circuit under the control of a second scanning signal provided by the second scanning line; the first reset circuit is electrically connected to a third scanning line, an initial voltage line and the anode of the light emitting element, respectively, and is configured to write an initial voltage provided by the initial voltage line into the anode of the light emitting element under the control of a third scanning signal provided by the third scanning line.

In a third aspect, an embodiment of the present disclosure provides a driving method, applied to the display device, wherein a display period includes N display phases; an nth display phase includes an nth data writing-in phase set in sequence; N is an integer greater than 1, and n is a positive integer less than or equal to N; the driving method includes: in at least part of the time period included in the nth data writing-in phase, writing, by the data writing-in circuit included in an (2n-1)th row of sub-pixels, the data voltage into a second terminal of an energy storage circuit included in the (2n-1)th row of sub-pixels under the control of the first scanning signal provided by the first scanning line of the (2n-1)th row, and writing, by the data writing-in circuit included in the 2nth row of sub-pixels, the data voltage into a second terminal of an energy storage circuit included in the 2nth row of sub-pixels under the control of the first scanning signal provided by the first scanning line of the 2nth row.

Optionally, the nth data writing-in phase includes an nth first writing-in time period and an nth second writing-in time period; the driving method includes: in the nth first writing-in time period, writing, by the data writing-in circuit included in the (2n-1)th row of sub-pixels, the data voltage into the second terminal of the energy storage circuit included in the (2n-1)th row of sub-pixels under the control of the first scanning signal provided by the first scanning line of the (2n-1)th row; in the nth second writing-in time period, writing, by the data writing-in circuit included in the 2nth row of sub-pixels, the data voltage into the second terminal of the energy storage circuit included in the 2nth row of sub-pixels under the control of the first scanning signal provided by the first scanning line of the 2nth row; wherein the nth first writing-in time period and the nth second writing-in time period overlap at least partially.

### BRIEF DESCRIPTION OF THE DRAWINGS

FIG. 1 is a circuit diagram of one row and six columns of sub-pixels included in a display panel described in at least one embodiment of the present disclosure;

FIG. 2 is a first layout diagram of the display panel shown in FIG. 1 according to at least one embodiment of the present disclosure;

FIG. 3A and FIG. 3B are layout diagrams of the semiconductor layer in FIG. 2;

FIG. 4 is a layout diagram of the first gate metal layer in FIG. 2;

FIG. 5 is a layout diagram of the second gate metal layer in FIG. 2;

FIG. 6 is a layout diagram of the first source-drain metal layer in FIG. 2;

FIG. 7 is a layout diagram of the second source-drain metal layer in FIG. 2;

FIG. 8 is a layout diagram of the first ITO layer in FIG. 2;

FIG. 9 is a layout diagram of FIG. 2 without the first ITO layer;

FIG. 10 is a schematic diagram of the superposition of the via holes in the semiconductor layer, the first gate metal layer, the second gate metal layer, the first source-drain metal layer and the first planarization layer in FIG. 2;

FIG. 11 is a schematic diagram of the superposition of via holes in the semiconductor layer, the first gate metal layer, the second gate metal layer, the first source-drain metal layer, the first planarization layer, the second source-drain metal layer and the second planarization layer in FIG. 2.

FIG. 12 is a schematic diagram of the superposition of vial holes in the semiconductor layer, the first gate metal layer, the second gate metal layer, and the first insulating layer in FIG. 2;

FIG. 13 is a second layout diagram of the display panel shown in FIG. 1;

FIG. 14 is a schematic diagram of the structure of the first ITO layer in FIG. 13;

FIG. 15 is a layout diagram of the film layer other than the second ITO layer in FIG. 13;

FIG. 16 is an enlarged schematic diagram of the first area AA1 in FIG. 15;

FIG. 17 is a circuit diagram of one row and six columns of sub-pixels included in the display panel described in at least one embodiment of the present disclosure;

FIG. 18 is a schematic diagram of the layout of the display panel shown in FIG. 2 provided with the first pixel defining layer;

FIG. 19A is a schematic diagram of adding a second pixel defining layer on the basis of FIG. 18;

FIG. 19B is a structural diagram of a display panel according to at least one embodiment of the present disclosure;

FIG. 19C is a structural diagram of a display panel according to at least one embodiment of the present disclosure;

FIG. 19D is a structural diagram of a display panel according to at least one embodiment of the present disclosure;

FIG. 19E is a structural diagram of a display panel according to at least one embodiment of the present disclosure;

FIG. 20 is a layout diagram of the first pixel defining layer in FIG. 19A;

FIG. 21 is a schematic diagram of the openings of the second pixel defining layer in FIG. 19A;

FIG. 22 is a schematic diagram of superposition of the openings in the first pixel defining layer and the second pixel defining layer;

FIG. 23 is a schematic diagram of the layout of the first pixel defining layer in FIG. 22;

FIG. 24 is a schematic diagram of the first pixel defining layer arranged on the layout of the display panel shown in FIG. 2;

FIG. 25 is a schematic diagram of adding a second pixel defining layer on the basis of FIG. 24;

FIG. 26 is a layout diagram of the first pixel defining layer in FIG. 25;

FIG. 27 is a schematic diagram of the openings of the second pixel defining layer in FIG. 25;

FIG. 28 is a schematic diagram of the superposition of the openings in the first pixel defining layer and the second pixel defining layer in FIG. 25;

FIG. 29A is a cross-sectional view along A-A′ after forming the light emitting layer and cathode layer based on FIG. 19A;

FIG. 29B is a cross-sectional view of the display panel described in at least one embodiment of the present disclosure;

FIG. 30 is a structural diagram of the sub-pixel in the display panel described in at least one embodiment of the present disclosure;

FIG. 31 is a structural diagram of the sub-pixel in the display panel described in at least one embodiment of the present disclosure;

FIG. 32 is a circuit diagram of the sub-pixel in the display panel described in at least one embodiment of the present disclosure;

FIG. 33 is a working timing diagram of the sub-pixel shown in FIG. 32;

FIG. 34 is a working timing diagram of the sub-pixel shown in FIG. 32.

### DETAILED DESCRIPTION

The technical solutions in the embodiments of the present disclosure will be clearly and completely described below with reference to the accompanying drawings in the embodiments of the present disclosure. Obviously, the described embodiments are only some of the embodiments of the present disclosure, rather than all of the embodiments. Based on the embodiments in the present disclosure, all other embodiments obtained by those of ordinary skill in the art without making creative efforts fall within the scope of protection of the present disclosure.

The transistors used in all embodiments of the present disclosure may be thin film transistors, field effect transistors, or other devices with the same characteristics. In the embodiment of the present disclosure, in order to distinguish the two electrodes of the transistor except the gate electrode, one electrode is called the first electrode and the other electrode is called the second electrode.

In actual operation, when the transistor is a thin film transistor or a field effect transistor, the first electrode may be a drain electrode, and the second electrode may be a source electrode; or, the first electrode may be a source electrode, the second electrode may be a drain electrode.

The display panel described in the embodiment of the present disclosure includes a base substrate and a plurality of pixel opening areas arranged on the base substrate, and also includes at least one planarization layer and at least two conductive layers stacked on the base substrate, wherein one planarization layer is arranged between adjacent conductive layers, and the planarization layer has a first type of via hole and a second type of via hole;

The display panel includes a signal line for transmitting a reference voltage signal, and a signal line for transmitting a power supply voltage signal;

The signal line for transmitting the reference voltage signal includes a first signal line and a second signal line; the first signal line is electrically connected to the second signal line through the first type of via hole;

The signal line for transmitting the power supply voltage signal includes a third signal line and a fourth signal line, and the third signal line is electrically connected to the fourth signal line through the second type of via hole;
an orthographic projection of the first type of via hole on the base substrate does not overlap an orthographic projection of the pixel opening area on the base substrate;
an orthographic projection of the second type of via hole on the base substrate does not overlap the orthographic projection of the pixel opening area on the base substrate.

In the display panel described in the embodiment of the present disclosure, the orthographic projections of the first type of via hole of the planarization layer and the second type of via hole of the planarization layer on the base substrate and the orthographic projections of the pixel opening area on the base substrate enable the light emitting material layer to be arranged on a flat surface, meet the requirements of the printing process for the flatness of the base substrate of the light emitting element, increase the stability of the light emitting element, and avoid the generation of Mura (uneven display).

Optionally, the reference voltage signal is a reference voltage signal and/or an initial voltage signal, and the power supply voltage signal can be a first voltage signal, but is not limited thereto.

In at least one embodiment of the present disclosure, the first voltage signal can be a high voltage signal.

In a specific implementation, when the display panel is working, current flows through the signal line for transmitting the reference voltage signal and the signal line for transmitting the power supply voltage signal, so the above signal lines can adopt a mesh structure to reduce the impact of uneven voltage drop on the display; the signal line for transmitting the reference voltage signal includes a first signal line and a second signal line located in different conductive layers; the signal line for transmitting the power supply voltage signal includes a third signal line and a fourth signal line located in different conductive layers; the first signal line and the second signal line are electrically connected to each other through the first type of via hole provided by the planarization layer, and the third signal line and the fourth signal line are electrically connected to each other through the second type of via hole provided by the planarization layer, and the first type of via hole and the second type of via hole avoid the pixel opening area, so that the light emitting material layer is arranged on a flat surface, meeting the printing process requirements for the flatness of the base substrate of the light emitting element, increasing the stability of the light emitting element, and avoiding the generation of Mura (uneven display).

In the related art, a printing process can be used to make a light emitting device. The printing process requires a highly flat substrate. If the base substrate is not flat or not flat enough, the light color and electrical characteristics of the light emitting device will be affected. The final result is that the light color of the light emitting device is deviated, and the efficiency, life and other characteristics of the light emitting device will also be greatly deteriorated.

Optionally, the thickness of the planarization layer can be greater than a first thickness threshold, and the first thickness threshold can be greater than or equal to 2.8 μm and less than or equal to 3.2 μm; for example, the first thickness threshold can be 3 μm.

In the specific implementation, since the thickness of the planarization layer is large, the via holes penetrating the planarization layer will affect the flatness of the base substrate, while the thickness of other insulating layers (such as the gate insulating layer, the interlayer dielectric layer, etc.) is small, so the via holes penetrating the other insulating layers have less requirements on the flatness of the base substrate.

In at least one embodiment of the present disclosure, when the display panel includes a first source-drain metal layer, a second source-drain metal layer, and a first ITO (indium tin oxide) layer stacked in sequence in a direction away from the base substrate, a first planarization layer may be arranged between the first source-drain metal layer and the second source-drain metal layer, and a second planarization layer may be arranged between the second source-drain metal layer and the first ITO layer;

When the display panel further includes a second ITO layer arranged on a side of the first ITO layer away from the base substrate, a third planarization layer may be arranged between the first ITO layer and the second ITO layer.

In at least one embodiment of the present disclosure, the display panel includes a first conductive layer, a second conductive layer, and a first planarization layer; the first conductive layer, the first planarization layer, and the second conductive layer are arranged in sequence along a direction away from the base substrate; the first signal line is a first reference signal line, and the second signal line is a first reference connection line; the first type of via hole includes a first via hole;

The first conductive layer includes the first reference signal line, and the second conductive layer includes the first reference connection line; the first type of via hole includes a first via hole;

The first planarization layer has the first via hole; the first reference signal line is electrically connected to the first reference connection line through the first via hole.

In specific implementation, the first reference signal line can be a reference voltage line or an initial voltage line, the first reference connection line can be a reference voltage connection line or an initial voltage connection line, the reference voltage line is used to provide a reference voltage for the sub-pixel, the initial voltage line is used to provide an initial voltage for the sub-pixel, the reference voltage connection line and the reference voltage line are located in different layers, and the reference voltage line is electrically connected to the reference voltage line; the initial voltage connection line and the initial voltage line are located in different layers, and the initial voltage connection line is electrically connected to the initial voltage line.

In at least one embodiment of the present disclosure, when the display panel is working, current flows through the signal line for providing the reference voltage and the signal line for providing the initial voltage, so a mesh structure is adopted to reduce the influence of uneven voltage drop on the display; and the first conductive layer includes the first reference signal line, the second conductive layer includes the first reference connection line, a first planarization layer is arranged between the first conductive layer and the second conductive layer, the first planarization layer has a first via hole, the first reference signal line and the first reference connection line are electrically connected through the first via hole, and since the first reference signal line and the first reference connection line need to be electrically connected through the first via hole of the first planarization layer, for the printing process, the position of the first via hole needs to be isolated from the pixel opening area to avoid affecting the display. Based on this, the first reference connection line can be set at the center of the pixel, and the first via hole can be set to avoid the pixel opening area to reduce the influence of the via hole of the planarization layer on the display.

Optionally, the first conductive layer may be a first source-drain metal layer, and the second conductive layer may be a second source-drain metal layer; the first reference connection line may extend along a first direction, and the first reference signal line may extend along a second direction, the first direction may be a vertical direction, and the second direction may be a horizontal direction.

In a specific implementation, a first planarization layer and a first passivation layer may be provided between the first source-drain metal layer and the second source-drain metal layer, and the first planarization layer functions to increase the thickness between the first source-drain metal layer and the second source-drain metal layer, reduce the parasitic capacitance of the wiring, and meet the requirements of driving a large-size load.

In at least one embodiment of the present disclosure, the display panel further includes a third conductive layer; the first conductive layer includes a second reference signal line; the third conductive layer includes a second reference connection line; the second reference signal line is electrically connected to the second reference connection line.

The third conductive layer is provided between the base substrate and the first conductive layer;

The first reference connection line and the second reference connection line both extend along the first direction;

The orthographic projections of the two second reference connection lines on the base substrate are arranged on opposite sides of the orthographic projections of the first reference connection line on the base substrate.

In a specific implementation, when the first reference signal line is a reference voltage line and the first reference connection line is a reference voltage connection line, the second reference signal line may be an initial voltage line and the second reference connection line may be an initial voltage connection line;

When the first reference signal line is an initial voltage line and the first reference connection line is an initial voltage connection line, the second reference signal line may be a reference voltage line and the second reference connection line may be a reference voltage connection line.

In at least one embodiment of the present disclosure, the orthographic projection of the second reference connection line on the base substrate may be adjacent to the orthographic projection of the first reference connection line on the base substrate.

Optionally, the third conductive layer may be a first gate metal layer; the first conductive layer may be a first source-drain metal layer; the third conductive layer includes a second reference connection line and the first conductive layer includes a second reference signal line; the second reference signal line and the second reference connection line are located in different layers, and the second reference signal line and the second reference connection line are electrically connected through a via hole.

In at least one embodiment of the present disclosure, since the second reference connection line is located in the first gate metal layer, and the square resistance Rs of the first gate metal layer is relatively large, it is necessary to use the second reference connection line arranged on the opposite sides of the first reference connection line (the first reference connection line and the second reference connection line are located in different layers), and the first reference connection line is arranged in the center of the pixel. This wiring can solve the problem that the via hole in the planarization layer affects the pixel opening area, and also avoids the short circuit risk between the first reference connection line and the second reference connection line.

In the specific implementation, since the gate metal layer can only use the Mo (molybdenum)-A1 (aluminum)-Mo structure in the low temperature polycrystalline silicon-n type (Ltps-ntype) process, the square resistance Rs of the gate metal layer is relatively large, which cannot meet the requirements of large-size driving loads. At least one embodiment of the present disclosure uses a source-drain metal layer (the source-drain metal layer can use a Ti (titanium)-Al-Ti structure, for example) to make a scanning line, a light emitting control line and a voltage signal line, and the scanning line and the light emitting control line are electrically connected to the gate electrode of the transistor in the sub-pixel through a via hole.

In at least one embodiment of the present disclosure, the display panel includes a first conductive layer, a second conductive layer, and a first planarization layer; the first conductive layer, the first planarization layer and the second conductive layer are arranged in sequence along a direction away from the base substrate; the third signal line is a first voltage line, and the fourth signal line is a first voltage connection line; the second type of via hole includes a second via hole;

The first conductive layer includes the first voltage line, and the second conductive layer includes the first voltage connection line;

The first planarization layer has the second via hole; the first voltage line is electrically connected to the first voltage connection line through the second via hole.

In specific implementation, the first conductive layer can be a first source-drain metal layer, the second conductive layer can be a second source-drain metal layer, the first conductive layer can include a first voltage line extending along the second direction, the second conductive layer can include a first voltage connection line extending along the first direction, the first voltage line is electrically connected to the first voltage connection line through the second via hole of the first planarization layer, the second via hole avoids the pixel opening area, and reduces the influence of the via hole of the planarization layer on the display.

Optionally, the first voltage line can be a high voltage line, the first voltage line can be used to directly provide a high voltage signal to the sub-pixel, and the first voltage connection line is electrically connected to the first voltage line.

In the embodiment of the present disclosure, the signal line for providing the reference voltage, the signal line for providing the initial voltage, and the voltage line for providing the high voltage signal need to have current passing through in the compensation phase, the reset phase and the light emitting phase. In order to maintain the signal integrity, it is necessary to use a conductive layer wiring with a low Rs. In at least one embodiment of the present disclosure, the first source-drain metal layer and the second source-drain metal layer have a low Rs.

Optionally, the light emitting element in the sub-pixel can be an organic light emitting diode, but is not limited to this. In actual operation, the light emitting element can also be a light emitting diode of other types. In at least one embodiment of the present disclosure, the display panel includes a plurality of sub-pixels arranged on the base substrate; the sub-pixels include light emitting elements;

The display panel includes a second conductive layer, an anode planarization layer and a fourth conductive layer stacked in a direction away from the base substrate; the fourth conductive layer includes the anode of the light emitting element;

The thickness of the anode planarization layer is greater than the thickness of the planarization layer.

Optionally, the fourth conductive layer may be a first indium tin oxide (ITO) layer, the second conductive layer may be a second source-drain metal layer, and a thicker anode planarization layer may be provided between the second conductive layer and the fourth conductive layer to improve the flatness of the base substrate of the light emitting element;

The thickness of the anode planarization layer is greater than the thickness of the planarization layer.

For example, the thickness of the anode planarization layer may be greater than a second thickness threshold;

The second thickness threshold may be greater than or equal to 3.5 μm and less than or equal to 4 μm, but is not limited thereto.

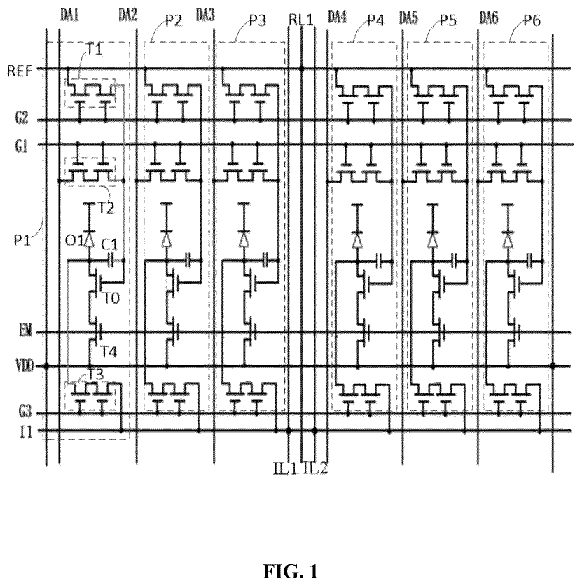

FIG. 1 is a circuit diagram of one row and six columns of sub-pixels included in a display panel according to at least one embodiment of the present disclosure.

As shown in FIG. 1, the first sub-pixel P1 located in the first column includes an organic light emitting diode O1, a storage capacitor C1, a first reset transistor T3, a data writing-in transistor T2, a second reset transistor T1, a driving transistor T0 and a light emitting control transistor T4;

The gate electrode of the first reset transistor T3 is electrically connected to the third scanning line G3, the first electrode of the first reset transistor T3 is electrically connected to the anode of the organic light emitting diode O1, and the second electrode of the first reset transistor T3 is electrically connected to the initial voltage line I1;

The anode of the organic light emitting diode O1 is electrically connected to the first electrode plate of the storage capacitor C1; the second electrode plate of the storage capacitor C1 is electrically connected to the second electrode of the data writing-in transistor T2;

The gate electrode of the data writing-in transistor T2 is electrically connected to the first scanning line G1, the first electrode of the data writing-in transistor T2 is electrically connected to the first column data line DA1;

The gate electrode of the second reset transistor T1 is electrically connected to the second scanning line G2, the first electrode of the second reset transistor T1 is electrically connected to the reference voltage line REF, and the second electrode of the second reset transistor T1 is electrically connected to the second electrode of the data writing-in transistor T2;

The gate electrode of the driving transistor T0 is electrically connected to the second electrode plate of the storage capacitor, the first electrode of the driving transistor T0 is electrically connected to the anode of the organic light emitting diode O1, and the second electrode of the driving transistor T0 is electrically connected to the first electrode of the light emitting control transistor T4;

The gate electrode of the light emitting control transistor T4 is electrically connected to the light emitting control line EM, and the second electrode of the light emitting control transistor T4 is electrically connected to the high voltage line VDD.

In at least one embodiment shown in FIG. 1, the light emitting element is an organic light emitting diode.

In at least one embodiment shown in FIG. 1, the transistor in the sub-pixel is an n-type low temperature polysilicon (LTPS) transistor. Since the leakage current of the n-type LTPS transistor is large, T1, T2 and T3 can all adopt a dual-channel series architecture.

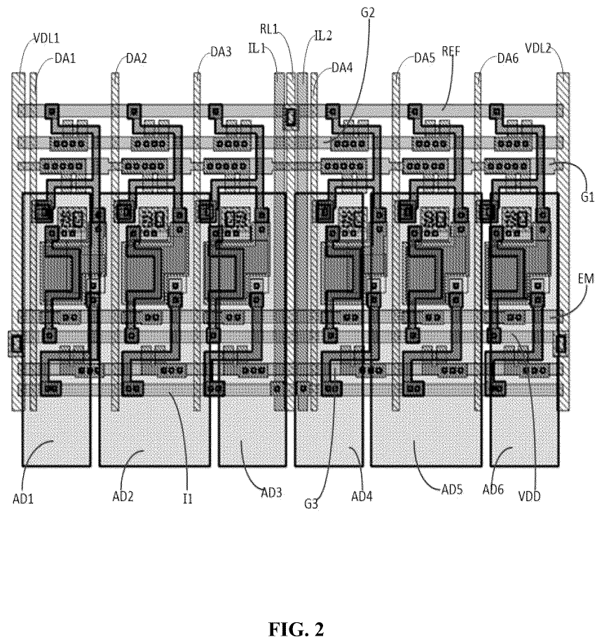

In FIG. 1 and FIG. 2, the second column data line is labeled DA2, the third column data line is labeled DA3, the fourth column data line is labeled DA4, the fifth column data line is labeled DA5, and the sixth column data line is labeled DA6;

The first high voltage connection line is labeled VDL1, the second high voltage connection line is labeled VDL2, the first initial voltage connection line is labeled IL1, the second initial voltage connection line is labeled IL2, and the first reference voltage connection line is labeled RL1.

As shown in FIG. 1, the first pixel unit includes a first sub-pixel P1, a second sub-pixel P2 and a third sub-pixel P3 arranged from left to right, and the second pixel unit includes a fourth sub-pixel P4, a fifth sub-pixel P5 and a sixth sub-pixel P6 arranged from left to right;

The first pixel unit and the second pixel unit form one pixel module;

The first reference voltage connection line RL1, the first initial voltage connection line IL1 and the second initial voltage connection line IL2 are all arranged between the first pixel unit and the second pixel unit;

The first reference voltage connection line RL1 is arranged in the middle position of the pixel module, IL1 is arranged on the left side of RL1, and IL2 is arranged on the right side of RL1; IL1 is adjacent to RL1, and IL2 is adjacent to RL1.

In at least one embodiment shown in FIG. 1, P1 and P4 can be red sub-pixels, P2 and P5 can be green sub-pixels, and P3 and P6 can be blue sub-pixels.

In at least one embodiment of the present disclosure, P2 and P5 can also be replaced by blue sub-pixels, and P3 and P6 can also be replaced by green sub-pixels.

In at least one embodiment shown in FIG. 1, IL1 and IL2 may be located in the first gate metal layer, RL1 may be located in the second source-drain metal layer, and REF, G2, G1, EM, VDD, G3, and I1 may be located in the first source-drain metal layer;

REF, G2, G1, EM, VDD, G3, and I1 may extend in the horizontal direction;

VDL1, DA1, DA2, DA3, IL1, RL1, IL2, DA4, DA5, DA6, and VDL2 all extend in the vertical direction.

In FIG. 1, the first sub-pixel is labeled P1, the second sub-pixel is labeled P2, the third sub-pixel is labeled P3, the fourth sub-pixel is labeled P4, the fifth sub-pixel is labeled P5, and the sixth sub-pixel is labeled P6.

FIG. 2 is a first layout diagram of the display panel shown in FIG. 1.

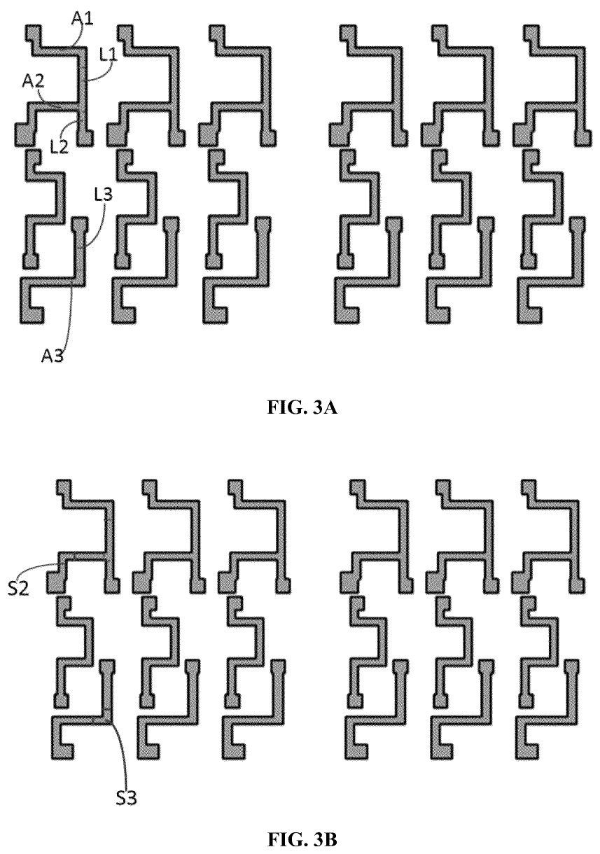

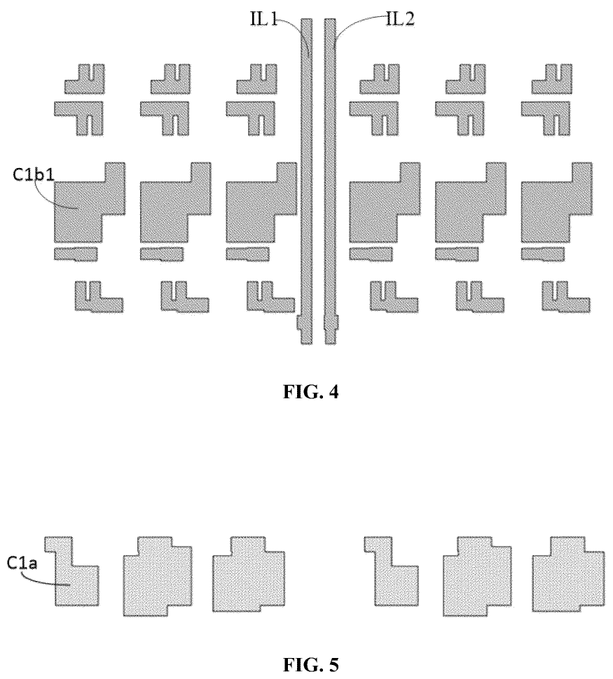

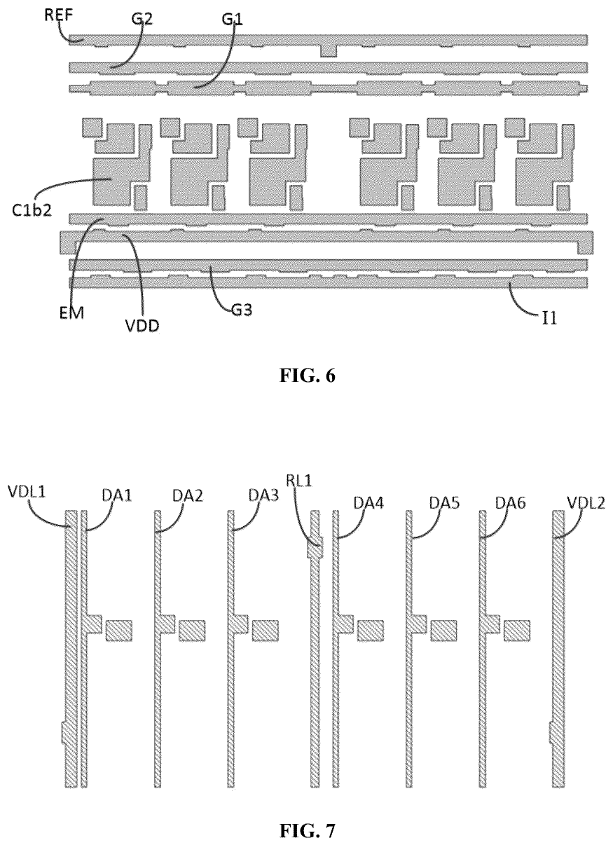

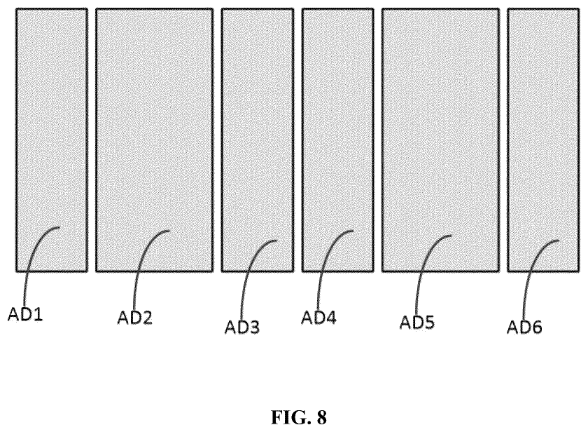

FIG. 3A and FIG. 3B are layout diagrams of the semiconductor layer in FIG. 2, FIG. 4 is a layout diagram of the first gate metal layer in FIG. 2, FIG. 5 is a layout diagram of the second gate metal layer in FIG. 2, FIG. 6 is a layout diagram of the first source-drain metal layer in FIG. 2, FIG. 7 is a layout diagram of the second source-drain metal layer in FIG. 2, and FIG. 8 is a layout diagram of the first ITO layer in FIG. 2.

In FIG. 2, AD1 is the anode of the organic light emitting diode in the first sub-pixel, AD2 is the anode of the organic light emitting diode in the second sub-pixel, AD3 is the anode of the organic light emitting diode in the third sub-pixel, AD4 is the anode of the organic light emitting diode in the fourth sub-pixel, AD5 is the anode of the organic light emitting diode in the fifth sub-pixel, and AD6 is the anode of the organic light emitting diode in the sixth sub-pixel.

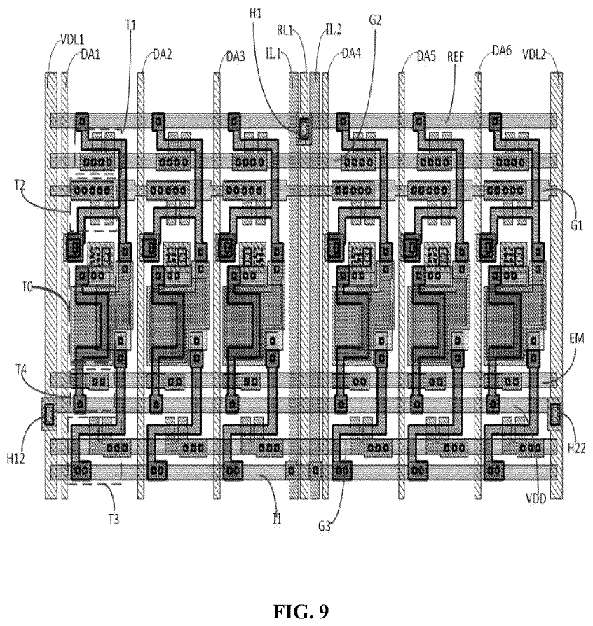

FIG. 9 is a layout diagram in FIG. 2 without the first ITO layer.

In FIG. 3A, A3 is an active pattern of the first reset transistor T3, A2 is an active pattern of the data write transistor T2, and A1 is an active pattern of the second reset transistor T1.

In FIG. 3B, S2 is a first electrode of the data writing-in transistor T2, and S3 is a first electrode of the first reset transistor T3.

In FIG. 4, C1b1 is a first electrode plate portion included in the second electrode plate of the storage capacitor C1, and in FIG. 6, C1b2 is a second electrode plate portion included in the second electrode plate of the storage capacitor C1, and the second electrode plate of the storage capacitor C1 includes a first electrode plate portion C1b1 and a second electrode plate portion C1b2 electrically connected to each other through a via.

In FIG. 5, C1a is a first electrode plate of the storage capacitor C1.

As shown in FIGS. 2-12, the first reference voltage connection line RL1 is electrically connected to the reference voltage line REF through the first via hole H1;

The first reference voltage connection line RL1 is located in the second source-drain metal layer, the reference voltage line REF is located in the first source-drain metal layer, the first via hole H1 is a via hole in the first planarization layer, and the first via hole H1 avoids the pixel opening area.

As shown in FIGS. 2-12, the first high voltage connection line VDL1 is electrically connected to the high voltage line VDD through the first second via hole H12;

The second high voltage connection line VDL2 is electrically connected to the high voltage line VDD through the second second via hole H22;

VDL1 and VDL2 are located in the second source-drain metal layer, and VDD is located in the first source-drain metal layer; H12 and H22 are via holes in the first planarization layer, and H12 and H22 avoid the pixel opening area.

In at least one embodiment of the present disclosure, the planarization layer may have a third type of via hole;

The display panel includes a plurality of sub-pixels arranged on the base substrate; the sub-pixels include a light emitting element, a storage capacitor, and a plurality of transistors;

The sub-pixels include a plurality of conductive portions, the plurality of conductive portions include an anode of the light emitting element, electrode plates of the storage capacitor, and an electrode of the transistor;

Some of the plurality of conductive portions are electrically connected through the third type of via hole;

The orthographic projection of the third type of via hole on the base substrate does not overlap the orthographic projection of the pixel opening area on the base substrate.

In specific implementation, the anode of the light emitting element and some electrodes of some transistors in the sub-pixel can be electrically connected through the third type of via hole on the planarization layer, and the anode of the light emitting element and one electrode plate of the storage capacitor can be electrically connected through the third type of via hole on the planarization layer. The third type of via hole avoids the pixel opening area, so that the light emitting material layer is arranged on a flat surface, which meets the printing process requirements for the flatness of the base substrate of the light emitting element, increases the stability of the light emitting element, and avoids the generation of Mura (uneven display).

In at least one embodiment of the present disclosure, the planarization layer has a fourth type of via hole;

The display panel includes a plurality of data lines and a plurality of sub-pixels arranged on the base substrate;
some electrodes of some transistors in the sub-pixels are electrically connected to the data lines through the fourth type of via holes;

The orthographic projection of the fourth type of via holes on the base substrate does not overlap the orthographic projection of the pixel opening area on the base substrate.

In specific implementation, some electrodes of some transistors in the sub-pixels are electrically connected to the data lines through the fourth type of via holes on the planarization layer, and the fourth type of via holes avoid the pixel opening area, so that the light emitting material layer is arranged on a flat surface, meeting the requirements of the printing process for the flatness of the base substrate of the light emitting element, increasing the stability of the light emitting element, and avoiding the generation of Mura (uneven display).

In at least one embodiment of the present disclosure, the via holes on each of the planarization layers can avoid the pixel opening area to improve the flatness of the base substrate of the light emitting element, but it is not limited thereto. In actual operation, at least part of the via holes on each of the planarization layers avoid the pixel opening area.

Optionally, the display panel includes a plurality of sub-pixels arranged on the base substrate; the sub-pixels include a first reset transistor; the third type of via holes include a third via and a fourth via;

The display panel also includes a semiconductor layer, a first conductive layer, a first planarization layer, a second conductive layer, a second planarization layer and a fourth conductive layer arranged in sequence in a direction away from the base substrate; the semiconductor layer includes a first electrode of the first reset transistor, and the fourth conductive layer includes an anode of the light emitting element; the first planarization layer has the third via hole, and the second planarization layer has the fourth via hole;

The first electrode of the first reset transistor is electrically connected to the anode of the light emitting element through the third via hole and the fourth via hole.

In a specific implementation, the first conductive layer may be a first source-drain metal layer, the second conductive layer may be a second source-drain metal layer, the fourth conductive layer may be a first ITO (indium tin oxide) layer, a first planarization layer is provided between the first source-drain metal layer and the second source-drain metal layer, a second planarization layer is provided between the second source-drain metal layer and the first ITO layer, the first electrode of the first reset transistor is located in the semiconductor layer, the anode of the light emitting element may be located in the first ITO layer, the first electrode of the first reset transistor is electrically connected to the anode of the light emitting element through the third via hole provided in the first planarization layer, and the fourth via hole provided in the second planarization layer is electrically connected to the anode of the light emitting element. The third via hole and the fourth via hole avoid the pixel opening area, reducing the influence of the via hole provided in the planarization layer on the display.

In at least one embodiment of the present disclosure, a second passivation layer and a second planarization layer may be provided between the second source-drain metal layer and the first ITO layer, and the second planarization layer functions to increase the thickness between the second source-drain metal layer and the first ITO layer, reduce the parasitic capacitance of the wiring, and meet the requirements of large-size load driving.

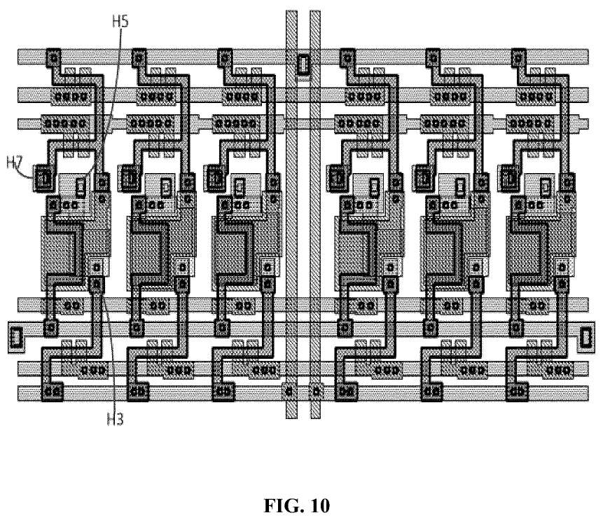

FIG. 10 is a schematic diagram of the superposition of the via holes in the semiconductor layer, the first gate metal layer, the second gate metal layer, the first source-drain metal layer, and the first planarization layer in FIG. 2;

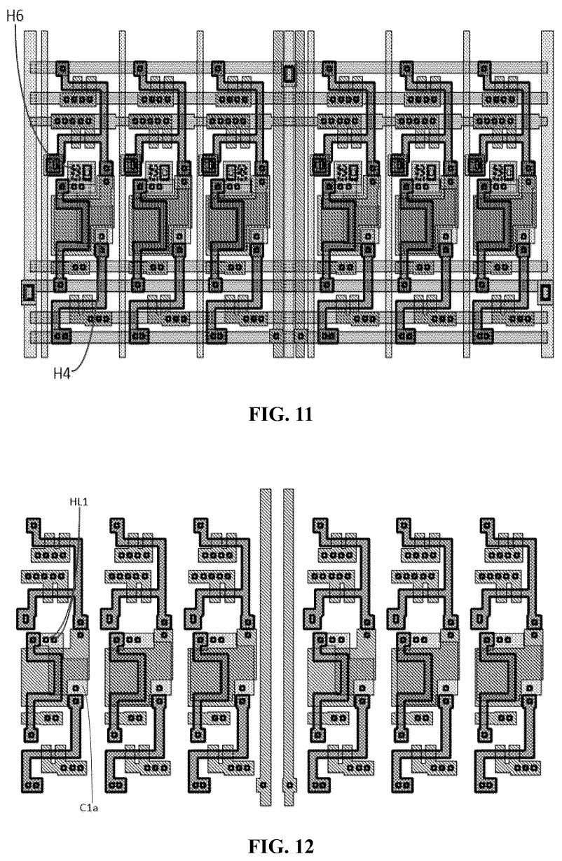

FIG. 11 is a schematic diagram of the superposition of via holes in the semiconductor layer, the first gate metal layer, the second gate metal layer, the first source-drain metal layer, the first planarization layer and the via holes in the second source-drain metal layer and the second planarization layer in FIG. 2.

FIG. 12 is a schematic diagram of the superposition of the via holes in the semiconductor layer, the first gate metal layer, the second gate metal layer, and the first insulating layer (the first insulating layer may be an interlayer dielectric layer) in FIG. 2.

In FIG. 10, H3 is the third via hole, and in FIG. 11, H4 is the fourth via hole;

As shown in FIG. 1-FIG. 11, the first electrode S3 of the first reset transistor is electrically connected to the anode AD1 of the organic light emitting diode in the first sub-pixel through the third via hole H3 and the fourth via hole H4.

In at least one embodiment of the present disclosure, the third type of via holes includes a fifth via hole and a sixth via hole;

The display panel also includes a fifth conductive layer, a first insulating layer, a first conductive layer, a first planarization layer, a second conductive layer, a second planarization layer and a fourth conductive layer arranged in sequence along a direction away from the base substrate;

The fourth conductive layer includes the anode of the light emitting element; the fifth conductive layer includes the first electrode plate of the storage capacitor;

The first planarization layer has the fifth via hole, and the second planarization layer has the sixth via hole;

The anode of the light emitting element is electrically connected to the first electrode plate of the storage capacitor through the sixth via hole, the fifth via hole, and the via hole penetrating the first insulating layer.

In a specific implementation, the fifth conductive layer may be a second gate metal layer, the first insulating layer may be a first insulating layer (the first insulating layer may be an interlayer dielectric layer), the first conductive layer may be a first source-drain metal layer, the second conductive layer may be a second source-drain metal layer, the fourth conductive layer may be a first ITO layer, an interlayer dielectric layer may be provided between the second gate metal layer and the first source-drain metal layer, a first planarization layer may be provided between the first source-drain metal layer and the second source-drain metal layer, a second planarization layer may be provided between the second source-drain metal layer and the first ITO layer, the anode of the light emitting element may be located in the first ITO layer, the first electrode plate of the storage capacitor may be located in the second gate metal layer, and the anode of the light emitting element may be electrically connected to the first electrode plate of the storage capacitor through a sixth via hole provided in the second planarization layer, a fifth via hole provided in the first planarization layer, and a first connection via hole penetrating the first insulating layer. The fifth via hole and the sixth via hole avoid the pixel opening area, reducing the influence of the via holes in the planarization layer on the display.

In FIG. 10, H5 is the fifth via hole, in FIG. 11, H6 is the sixth via hole, and in FIG. 12, HL1 is the first connection via hole.

As shown in FIG. 1-FIG. 12, the anode AD1 of the organic light emitting diode in the first sub-pixel is electrically connected to the first electrode plate C1a of the storage capacitor through the sixth via hole H6, the fifth via hole H5, and the first connection via hole HL1.

In at least one embodiment of the present disclosure, the sub-pixel includes a data writing-in transistor; the fourth type of via hole includes a seventh via;

The display panel also includes a semiconductor layer, a first conductive layer, a first planarization layer, and a second conductive layer arranged in sequence along a direction away from the base substrate;

The semiconductor layer includes the first electrode of the data writing-in transistor, and the second conductive layer includes the data line;

The first planarization layer has the seventh via hole, and the first electrode of the data writing-in transistor is electrically connected to the data line through the seventh via hole.

In a specific implementation, the first conductive layer may be a first source-drain metal layer, the second conductive layer may be a second source-drain metal layer, a first planarization layer is provided between the first source-drain metal layer and the second source-drain metal layer, the first electrode of the data writing-in transistor is located in the semiconductor layer, the data line is located in the second source-drain metal layer, and the first electrode of the data writing-in transistor is electrically connected to the data line through the seventh via hole of the first planarization layer. The seventh via hole avoids the pixel opening area, reducing the influence of the via hole of the planarization layer on the display

In FIG. 10, the seventh via hole is labeled H7.

As shown in FIGS. 1 to 10, the first electrode S1 of the data writing-in transistor is electrically connected to the first data line DA1 through the seventh via hole H7.

Optionally, the sub-pixel includes a first reset transistor; the third type of via hole includes a third via hole, a fourth via hole and an eighth via hole;

The display panel also includes a semiconductor layer, a first conductive layer, a first planarization layer, a second conductive layer, a second planarization layer, a fourth conductive layer, a third planarization layer and a sixth conductive layer arranged in sequence in a direction away from the base substrate;

The semiconductor layer includes the first electrode of the first reset transistor, and the sixth conductive layer includes the anode of the light emitting element; the first planarization layer has the third via hole, the second planarization layer has the fourth via hole, and the third planarization layer has the eighth via hole;

The first electrode of the first reset transistor is electrically connected to the anode of the light emitting element through the third via hole, the fourth via hole and the eighth via hole.

In a specific implementation, the first conductive layer may be a first source-drain metal layer, the second conductive layer may be a second source-drain metal layer, the fourth conductive layer may be a first ITO layer, the sixth conductive layer may be a second ITO layer, a first planarization layer may be provided between the first source-drain metal layer and the second source-drain metal layer, a second planarization layer may be provided between the second source-drain metal layer and the first ITO layer, a third planarization layer may be provided between the first ITO layer and the second ITO layer, the first electrode of the first reset transistor may be located in the semiconductor layer, the anode of the light emitting element may be located in the second ITO layer, the first electrode of the first reset transistor may be electrically connected to the anode of the light emitting element through the third via hole of the first planarization layer, the fourth via hole of the second planarization layer, and the eighth via hole of the third planarization layer, the third via hole, the fourth via hole and the eighth via hole avoid the pixel opening area, and reduce the influence of the via hole of the planarization layer on the display.

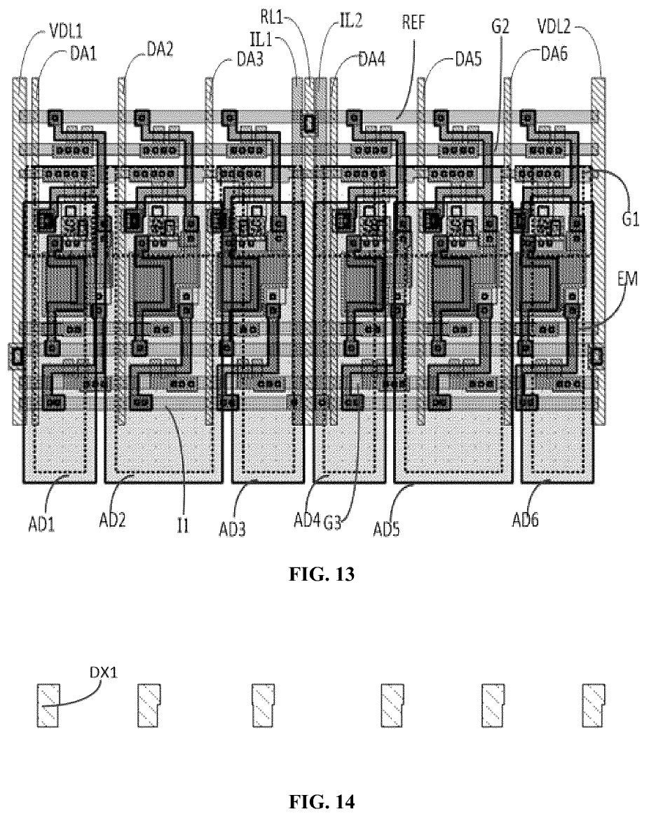

FIG. 13 is a second layout diagram of the display panel shown in FIG. 1.

In at least one embodiment of the display panel shown in FIG. 13, a semiconductor layer, a first gate metal layer, a second gate metal layer, a first source-drain metal layer, a second source-drain metal layer, a first ITO layer and a second ITO layer are sequentially stacked along a side away from the base substrate; a first insulating layer is arranged between the second gate metal layer and the first source-drain metal layer, a first planarization layer is arranged between the first source-drain metal layer and the second source-drain metal layer, a second planarization layer is arranged between the second source-drain metal layer and the first ITO layer, and a third planarization layer is arranged between the first ITO layer and the second ITO layer.

The structure of the semiconductor layer in FIG. 13 is shown in FIG. 3A, the structure of the first gate metal layer in FIG. 13 is shown in FIG. 4, the structure of the second gate metal layer in FIG. 13 is shown in FIG. 5, the structure of the first source-drain metal layer in FIG. 13 is shown in FIG. 6, the structure of the second source-drain metal layer in FIG. 13 is shown in FIG. 7, the structure of the first ITO layer in FIG. 13 is shown in FIG. 14, and the structure of the second ITO layer in FIG. 13 is shown in FIG. 8.

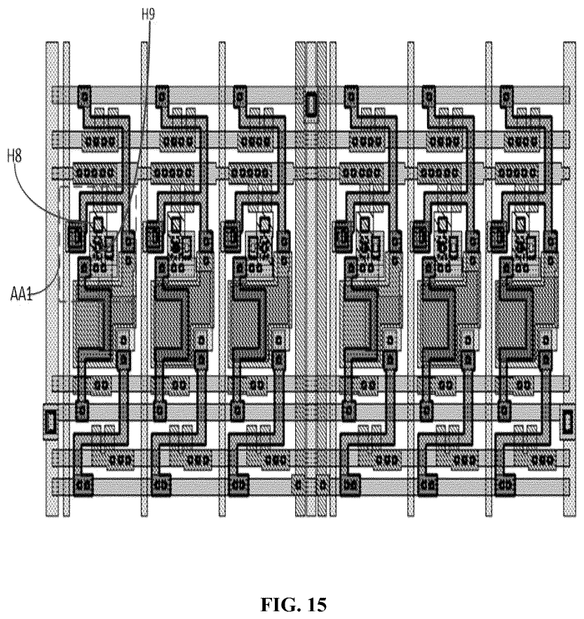

FIG. 15 is a layout diagram of the film layers except the second ITO layer in FIG. 13.

The difference between the second layout diagram shown in FIG. 13 and the second layout diagram shown in FIG. 2 is that: there are two ITO layers: a first ITO layer and a second ITO layer;

The second ITO layer includes an anode of a light emitting element;

The first ITO layer includes a first conductive pattern DX1.

As shown in FIG. 13, FIG. 10, FIG. 11 and FIG. 15, and FIG. 3A to FIG. 7, the first electrode S3 of the first reset transistor can be electrically connected to the anode AD1 of the organic light emitting diode in the first sub-pixel through the third via hole H3 of the first planarization layer, the fourth via hole H4 of the second planarization layer, and the eighth via hole H8 of the third planarization layer.

In the specific implementation, in order to improve the effect of the flattening effect of the pixel opening area on the printing device, at least one embodiment of the present disclosure adds a third planarization layer and a second ITO layer (due to the addition of a planarization layer, the flattening effect of the pixel opening area is better), and the anode of the light emitting element is set to be located in the second ITO layer. The first ITO layer includes a first conductive pattern DX1. The anode of the light emitting element is electrically connected to the first electrode of the first reset transistor through the first conductive pattern DX1. The anode of the light emitting element is a reflective anode. Since there is also a film layer wiring of the second source and drain metal layer at the opening, the third planarization layer is used for flattening, which improves the uneven printing problem caused by the film layer wiring of the second source-drain metal layer; the eighth via hole of the third planarization layer avoids the pixel opening area, and while improving the flattening of the printing, it has no effect on the size of the pixel opening area.

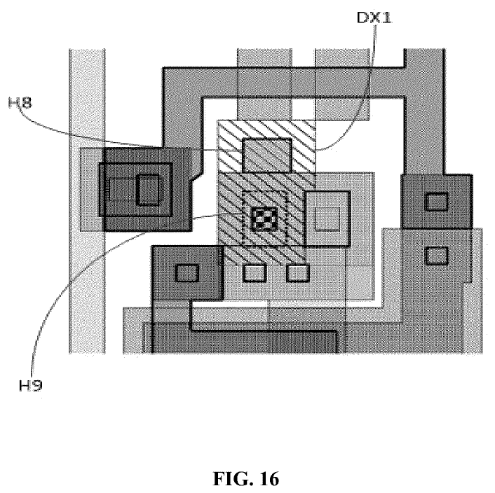

FIG. 16 is an enlarged schematic diagram of the first area AA1 in FIG. 15.

In FIG. 16, the eighth via hole is labeled H8, the ninth via hole is labeled H9, and the first conductive pattern is labeled DX1.

In at least one embodiment of the present disclosure, the third type of via holes includes a fifth via hole, a sixth via hole and a ninth via hole;

The display panel also includes a fifth conductive layer, a first insulating layer, a first conductive layer, a first planarization layer, a second conductive layer, a second planarization layer, a fourth conductive layer, a third planarization layer and a sixth conductive layer arranged in sequence in a direction away from the base substrate;

The sixth conductive layer includes the anode of the light emitting element, and the fifth conductive layer includes the first electrode plate of the storage capacitor;

The first planarization layer has the fifth via hole, the second planarization layer has the sixth via hole, and the third planarization layer has the ninth via hole;

The anode of the light emitting element is electrically connected to the first electrode plate of the storage capacitor through the ninth via hole, the sixth via hole, the fifth via hole, and the via hole penetrating the first insulating layer.

In a specific implementation, the fifth conductive layer may be a second gate metal layer, the first conductive layer may be a first source-drain metal layer, the second conductive layer may be a second source-drain metal layer, the fourth conductive layer may be a first ITO layer, the sixth conductive layer may be a second ITO layer, the anode of the light emitting element may be located in the second ITO layer, the second electrode plate of the storage capacitor may be located in the second gate metal layer, the anode of the light emitting element may be electrically connected to the first electrode plate of the storage capacitor through the ninth via hole of the third planarization layer, the sixth via hole of the second planarization layer, the fifth via hole of the first planarization layer, and the first connecting via hole penetrating the first insulating layer, the ninth via hole, the sixth via hole and the fifth via hole avoid the pixel opening area, reducing the influence of the via holes of the planarization layer on the display.

As shown in FIGS. 13, 10, 11, 12 and 15, and FIGS. 3A to 7, the anode AD1 of the organic light emitting diode in the first sub-pixel is electrically connected to the first electrode plate Cla of the storage capacitor through the ninth via hole H9, the sixth via hole H6, the fifth via hole H5, and the first connection via hole HL 1 that penetrates the first insulating layer.

In at least one embodiment of the present disclosure, the plurality of sub-pixels are divided into a plurality of pixel units arranged in an array; the pixel unit includes a plurality of sub-pixels arranged along a second direction; the first direction intersects the second direction;

N columns of the pixel units are arranged between two adjacent columns of the first reference connection lines; N is an integer greater than 1.

Optionally, the first direction may be a vertical direction, and the second direction may be a horizontal direction.

In a specific implementation, the pixel unit may include a plurality of sub-pixels arranged in the horizontal direction. For example, the pixel unit may include red sub-pixels, green sub-pixels and blue sub-pixels arranged in sequence in the horizontal direction. Every two columns of pixel units constitute a pixel unit column. The first reference connection line is located between the first column of pixel units included in the pixel unit column and the second column of pixel units included in the pixel unit column; that is, the first column of pixel units and the second column of pixel units constitute the first pixel unit column, the third column of pixel units and the fourth column of pixel units constitute the second pixel unit column, the first column of first reference connection lines are arranged between the first column of pixel units and the second column of pixel units, the second column of first reference connection lines are arranged between the third column of pixel units and the fourth column of pixel units, and no first reference connection lines are arranged between the second column of pixel units and the third column of pixel units.

In at least one embodiment of the present disclosure, the display panel further includes a plurality of rows and a plurality of columns of lens group arranged on a side of the pixel unit away from the base substrate; the lens group includes an odd numbered lenses;

The N pixel units located in the same row and arranged between two adjacent columns of first reference connection lines correspond to the same lens group.

In a specific implementation, the display panel further includes a plurality of rows and a plurality of columns of lens group arranged on a side of the pixel unit away from the base substrate, and the N pixel units in the same row arranged between two adjacent columns of first reference connection lines correspond to the same lens group, and the lens group may include an odd numbered lenses.

In at least one embodiment of the present disclosure, the pixel units arranged between different two adjacent columns of first reference connection lines correspond to different lens groups.

In a specific implementation, the pixel units between different two adjacent columns of first reference connection lines correspond to different lens groups.

Optionally, the lens may be a 3D lens.

For example, when the first column of pixel units and the second column of pixel units are arranged between the first column of first reference connection line and the second column of first reference connection line, and the third column of pixel units and the fourth column of pixel units are provided between the second column of first reference connection line and the third column of first reference connection line, the first column of first reference connection line and the second column of first reference connection line are the first group of adjacent two columns of first reference connection lines, the second column of first reference connection line and the third column of first reference connection line are the second group of adjacent two columns of first reference connection lines, the first group of adjacent two columns of first reference connection lines and the second group of adjacent two columns of first reference connection lines are different adjacent two columns of first reference connection lines, the first pixel unit column includes the first column of pixel units and the second column of pixel units, the second pixel unit column includes the third column of pixel units and the fourth column of pixel units, and the pixel units in the same row in the first column of pixel units and the second pixel unit column correspond to different lens groups.

In at least one embodiment of the present disclosure, the display panel includes a plurality of sub-pixels arranged on the base substrate; the sub-pixels include light emitting elements; the light emitting elements include light emitting layers;
the light emitting layers of the light emitting elements in the sub-pixels in the same column are continuous with each other and have the same color.

In the specific implementation, the light emitting layers of the light emitting elements in the sub-pixels in the same column are continuous with the same color.

Optionally, the sub-pixel includes a light emitting element, a storage capacitor, a first reset transistor, a data writing-in transistor and a second reset transistor;

The active pattern of the second reset transistor is electrically connected to the active pattern of the data writing-in transistor through a first connection line; the active pattern of the data writing-in transistor is electrically connected to the second electrode plate of the storage capacitor through a second connection line;

The anode of the light emitting element is electrically connected to the active pattern of the first reset transistor through a third connection line;

The first connection line, the second connection line and the third connection line are arranged in the same layer as the active pattern.

As shown in FIG. 3A, and FIG. 2, FIG. 4-FIG. 12, the active pattern A1 of the second reset transistor is electrically connected to the active pattern S2 of the data writing-in transistor through a first connection line L1;

The active pattern S2 of the data writing-in transistor is electrically connected to the second electrode plate of the storage capacitor through a second connection line L2;

The anode AD1 of the organic light emitting diode in the first sub-pixel is electrically connected to the active pattern A3 of the first reset transistor through a third connection line L3.

As shown in FIG. 3A, the first connection line L1, the second connection line L2 and the third connection line L3 are all located in the semiconductor layer, and the semiconductor layer is used as a long wire to enter the sub-pixel.

In the specific implementation, due to the relatively large leakage current of the n-type LTPS (low temperature polycrystalline silicon) transistor, under the premise that the sub-pixel in the display panel has a long light emitting time, it is easy to produce screen flickering and other phenomena. The resistance of the semiconductor layer is relatively large, so the first connection line, the second connection line and the third connection line are set to be located in the semiconductor layer, which can reduce the leakage current and improve the display effect.

In at least one embodiment of the present disclosure, the position of the reference voltage connection line can be interchanged with the position of the initial voltage connection line.

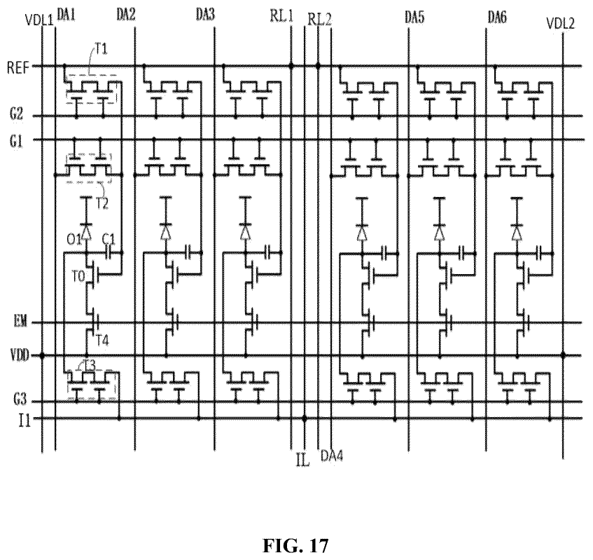

As shown in FIG. 17, the first reference voltage connection line RL1 and the second reference voltage connection line RL2 extend in the vertical direction, and the initial voltage connection line IL extends in the vertical direction;

The initial voltage connection line IL is electrically connected to the initial voltage line I1, RL1 is electrically connected to the reference voltage line REF, and RL2 is electrically connected to the reference voltage line REF;

The initial voltage connection line IL is arranged in the middle of two columns of pixel units, and does not affect the display of the pixel opening area;

RL1 is arranged on the left side of IL, and RL2 is arranged on the right side of IL, RL1 is adjacent to IL, and RL2 is adjacent to IL; the reference voltage connection line adopts two wirings of the first gate metal layer, which plays a role in reducing resistance.

In at least one embodiment shown in FIG. 17, the first reference voltage connection line RL1 and the second reference voltage connection line RL2 can be located in the first gate metal layer, the initial voltage connection line IL can be located in the second source-drain metal layer, and the reference voltage line REF and the initial voltage line I1 can be located in the first source-drain metal layer.

Through the layout design in at least one embodiment of the present disclosure, the signal line RC (resistance-capacitance) Loading wiring is optimized, and the flatness requirements of the printing process are considered, so that it is compatible with large-size loads, printing processes and variable frequency refresh requirements, providing technical support for large-size high PPI (pixel density) internal compensation display products.

In at least one embodiment of the present disclosure, the display panel includes a first pixel defining layer and a second pixel defining layer;

The second pixel defining layer forms a plurality of openings arranged along the second direction, and the openings extend along the first direction;

The first pixel defining layer includes a plurality of pixel defining portions arranged along the first direction, the pixel defining portions fill a part of the openings, and the plurality of pixel defining parts define a plurality of pixel opening areas in the plurality of openings.

Optionally, the pixel defining portion includes an integrated structure extending along the second direction; or,

The pixel defining portion includes a plurality of pixel defining patterns arranged along the second direction, and at least a part of the pixel defining patterns is filled in the corresponding openings.

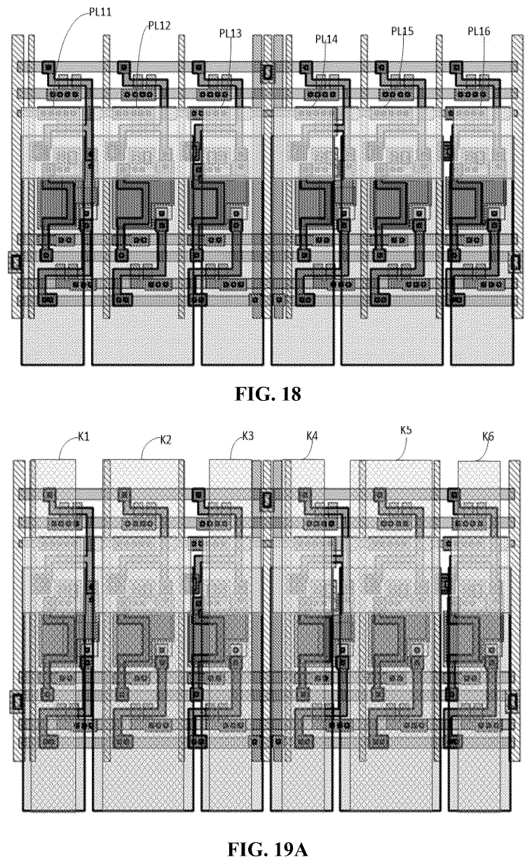

FIG. 18 is a schematic diagram of a first pixel defining layer arranged on the layout diagram of the display panel shown in FIG. 2.

In FIG. 18, the first pixel defining pattern is labeled PL11, the second pixel defining pattern is labeled PL12, the third pixel defining pattern is labeled PL13, the fourth pixel defining pattern is labeled PL 14, the fifth pixel defining pattern is labeled PL15, and the sixth pixel defining pattern is labeled PL16.

In each pixel defining pattern, a pixel defining material is provided.

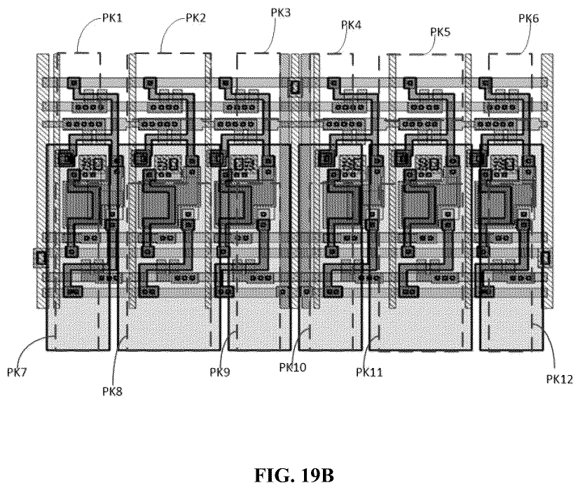

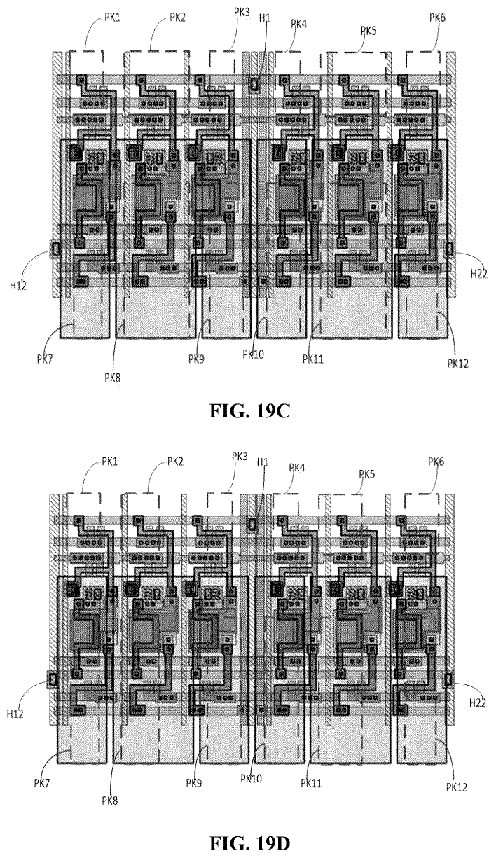

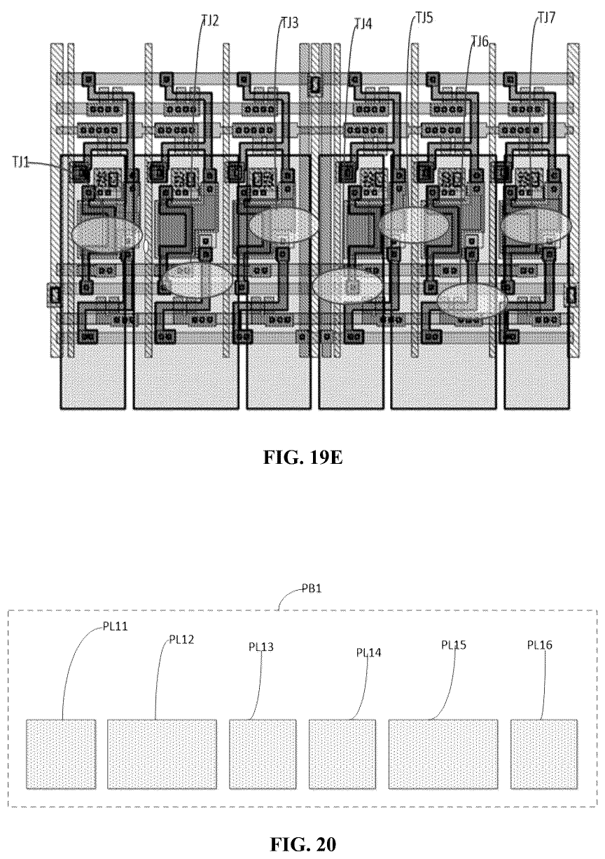

As shown in FIG. 19A, after the first pixel defining layer is made, the second pixel defining layer can be made;

In FIG. 19A, K1 is the first opening, K2 is the second opening, K3 is the third opening, K4 is the fourth opening, K5 is the fifth opening, and K6 is the sixth opening;

Pixel defining materials are made at positions other than the openings;

K1, K2, K3, K4, K5 and K6 are arranged in the horizontal direction,

K1, K2, K3, K4, K5 and K6 extend in the vertical direction.

As shown in FIG. 19A, the second pixel defining layer forms a first opening K1, a second opening K2, a third opening K3, a fourth opening K4, a fifth opening K5 and a sixth opening K6 arranged in the horizontal direction;

The first opening K1, the second opening K2, the third opening K3, the fourth opening K4, the fifth opening K5 and the sixth opening K6 extend in the vertical direction;

The first pixel defining layer includes a first pixel defining pattern PL1, a second pixel defining pattern PL2, a third pixel defining pattern PL3, a fourth pixel defining pattern PL4, a fifth pixel defining pattern PL5 and a sixth pixel defining pattern PL6;

PL1 fills a part of K1, PL2 fills a part of K2, PL3 fills a part of K3, PL4 fills a part of K4, PL5 fills a part of K5, and PL6 fills a part of K6, and each pixel defining portion defines a pixel opening area in each opening.

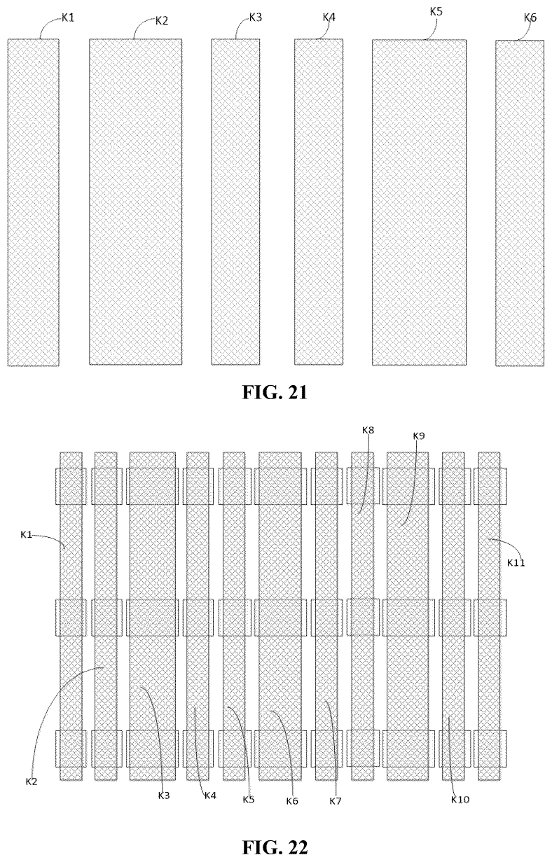

FIG. 20 is a layout diagram of the first pixel defining layer in FIG. 19A, and FIG. 21 is a schematic diagram of each opening of the second pixel defining layer in FIG. 19A.

As shown in FIG. 20, PL1, PL2, PL3, PL4, PL5, and PL6 may be included in the first pixel defining portion PB1.

As shown in FIG. 19B, in at least one embodiment of the present disclosure, the display panel includes a first pixel opening area PK1, a second pixel opening area PK2, a third pixel opening area PK3, a fourth pixel opening area PK4, a fifth pixel opening area PK5, a sixth pixel opening area PK6, a seventh pixel opening area PK7, an eighth pixel opening area PK8, a ninth pixel opening area PK9, a tenth pixel opening area PK10, an eleventh pixel opening area PK11, and a twelfth pixel opening area PK12 arranged on a base substrate; PK1, PK2, PK3, PK4, PK5, and PK6 are arranged in a horizontal direction; PK7, PK8, PK9, PK10, PK11, and PK12 are arranged in a horizontal direction; PK1 and PK7 are arranged in a vertical direction, PK2 and PK8 are arranged in a vertical direction, PK3 and PK9 are arranged in a vertical direction, PK4 and PK10 are arranged in a vertical direction, PK5 and PK11 are arranged in a vertical direction, and PK6 and PK12 are arranged in a vertical direction.

In at least one embodiment corresponding to FIG. 19B, each pixel opening area is defined by the first pixel defining layer and the second pixel defining layer in FIG. 19A.

As shown in FIG. 19C, in at least one embodiment of the present disclosure, the display panel includes a first pixel opening area PK1, a second pixel opening area PK2, a third pixel opening area PK3, a fourth pixel opening area PK4, a fifth pixel opening area PK5, a sixth pixel opening area PK6, a seventh pixel opening area PK7, an eighth pixel opening area PK8, a ninth pixel opening area PK9, a tenth pixel opening area PK10, an eleventh pixel opening area PK11, and a twelfth pixel opening area PK12 arranged on a base substrate; PK1, PK2, PK3, PK4, PK5, and PK6 are arranged in a horizontal direction; PK7, PK8, PK9, PK10, PK11, and PK12 are arranged in a horizontal direction; PK1 and PK7 are arranged in a vertical direction, PK2 and PK8 are arranged in a vertical direction, PK3 and PK9 are arranged in a vertical direction, PK4 and PK10 are arranged in a vertical direction, PK5 and PK11 are arranged in a vertical direction, and PK6 and PK12 are arranged in a vertical direction;

Compared with at least one embodiment corresponding to FIG. 19B, in at least one embodiment corresponding to FIG. 19C, the length of PK7 along the vertical direction, the length of PK8 along the vertical direction, the length of PK9 along the vertical direction, the length of PK10 along the vertical direction, the length of PK11 along the vertical direction, and the length of PK 12 along the vertical direction are reduced to avoid the third type of via holes and the fourth type of via holes between two adjacent pixel opening areas in the vertical direction;

The width of PK7 along the horizontal direction is narrowed, that is, the boundary line on the left side of PK7 is moved to the right to avoid the first second via hole H12;

The width of PK12 along the horizontal direction is narrowed, that is, the boundary line on the right side of PK 12 is moved to the left to avoid the second second via hole H22;

The width of PK3 along the horizontal direction is narrowed, that is, the boundary line on the right side of PK3 is moved to the left to avoid the first via hole H1;

The width of PK4 along the horizontal direction is narrowed, that is, the boundary line on the left side of PK4 is moved to the right to avoid the first via hole H1.

Compared with at least one embodiment corresponding to FIG. 19C, in at least one embodiment corresponding to FIG. 19E, the width of PK8 is narrowed in the horizontal direction, and the width of PK 11 is narrowed in the horizontal direction to avoid the fourth via hole;

The width of PK2 is narrowed in the horizontal direction, and the width of PK5 is narrowed in the horizontal direction.

As shown in FIG. 19E, the display panel further includes a lens group arranged on a side of each sub-pixel away from the base substrate; the lens group may include seven lenses: a first lens TJ1, a second lens TJ2, a third lens TJ3, a fourth lens TJ4, a fifth lens TJ5, a sixth lens TJ6, and a seventh lens TJ7.

FIG. 22 is a schematic diagram of the superposition of each opening of the first pixel defining layer and the second pixel defining layer.

In FIG. 22, K1 is the first opening of the second pixel defining layer, K2 is the second opening of the second pixel defining layer, K3 is the third opening of the second pixel defining layer, K4 is the fourth opening of the second pixel defining layer, K5 is the fifth opening of the second pixel defining layer, K6 is the sixth opening of the second pixel defining layer, K7 is the seventh opening of the second pixel defining layer, K8 is the eighth opening of the second pixel defining layer, K9 is the ninth opening of the second pixel defining layer, K10 is the tenth opening of the second pixel defining layer, and K11 is the eleventh opening of the second pixel defining layer.

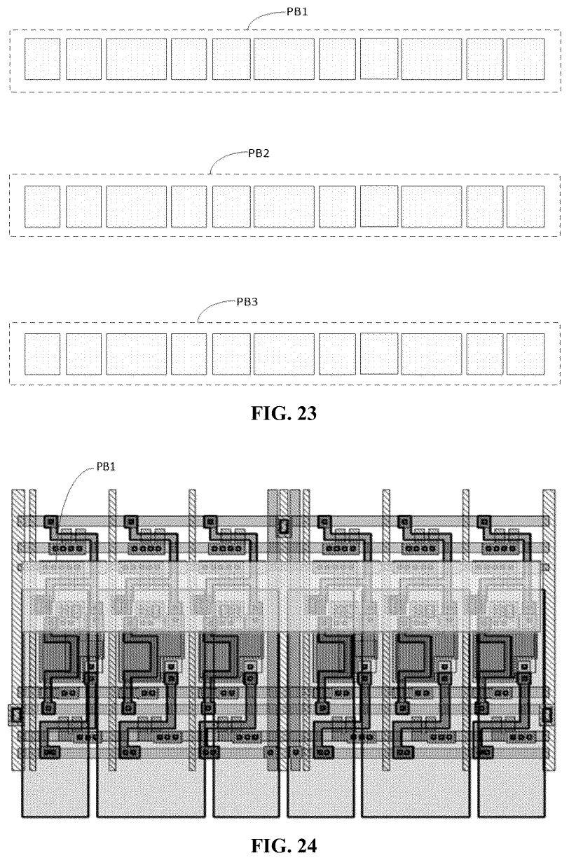

FIG. 23 is a layout diagram of the first pixel defining layer in FIG. 22

In FIG. 23, the first pixel defining portion is labeled PB1, the second pixel defining portion is labeled PB2, and the third pixel defining portion is labeled PB3;

The first pixel defining portion PB1, the second pixel defining portion PB2, and the third pixel defining portion PB3 are arranged in the vertical direction.

FIG. 24 is a schematic diagram of a first pixel defining layer arranged on the layout diagram of the display panel shown in FIG. 2.

In FIG. 24, the first pixel defining portion is labeled PB1;

The first pixel defining portion PB1 is an integrated structure extending in the horizontal direction.

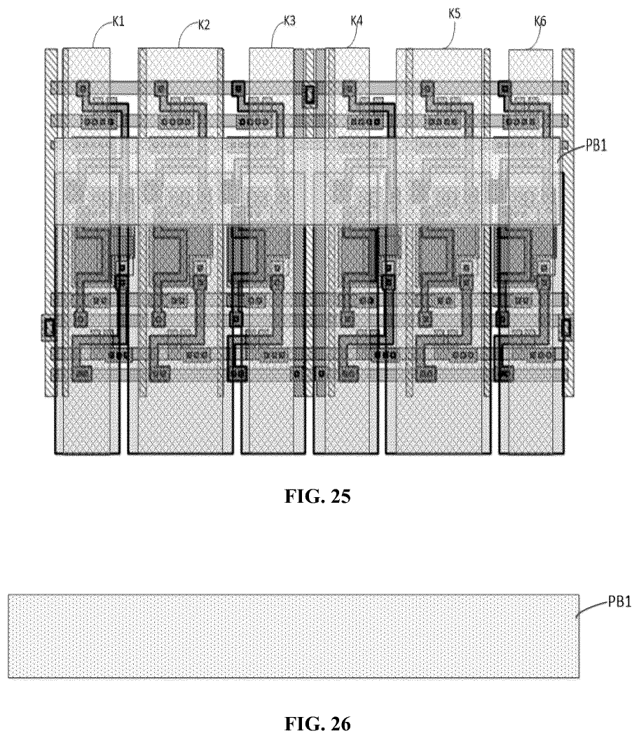

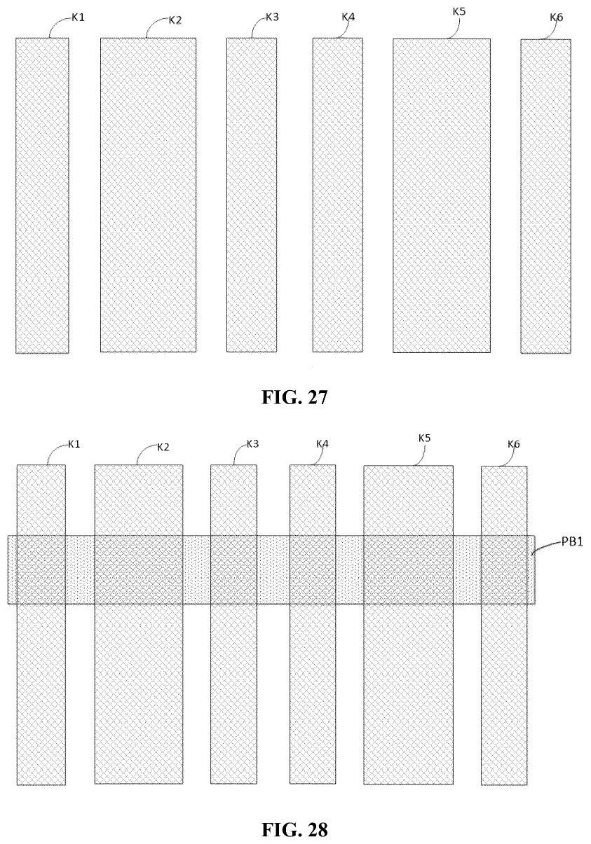

As shown in FIG. 25, after the first pixel defining layer is made, the second pixel defining layer can be made;

In FIG. 25, the first opening is labeled K1, the second opening is labeled K2, the third opening is labeled K3, the fourth opening is labeled K4, the fifth opening is labeled K5, and the sixth opening is labeled K6;

Pixel defining materials are made at positions other than the openings;

K1, K2, K3, K4, K5 and K6 are arranged in the horizontal direction,

K1, K2, K3, K4, K5 and K6 extend in the vertical direction.

As shown in FIG. 25, the second pixel defining layer forms a first opening K1, a second opening K2, a third opening K3, a fourth opening K4, a fifth opening K5 and a sixth opening K6 arranged in the horizontal direction;

The first opening K1, the second opening K2, the third opening K3, the fourth opening K4, the fifth opening K5 and the sixth opening K6 extend in the vertical direction;

PB1 fills a part of K1, PB1 fills a part of K2, PB1 fills a part of K3, PB1 fills a part of K4, PB1 fills a part of K5, PB1 fills a part of K6, and each pixel defining portion defines a pixel opening area in each opening.

FIG. 26 is a layout diagram of the first pixel defining layer in FIG. 25, and FIG. 26 is a schematic diagram of each opening of the second pixel defining layer in FIG. 24.

FIG. 28 is a schematic diagram of the superposition of each opening of the first pixel defining layer and the second pixel defining layer in FIG. 25.

In at least one embodiment of the present disclosure, the maximum distance between the first pixel defining layer and the base substrate is different from the maximum distance between the second pixel defining layer and the base substrate, so that the light emitting layers of the light emitting elements in the sub-pixels in the same column are continuous with each other and have the same color.

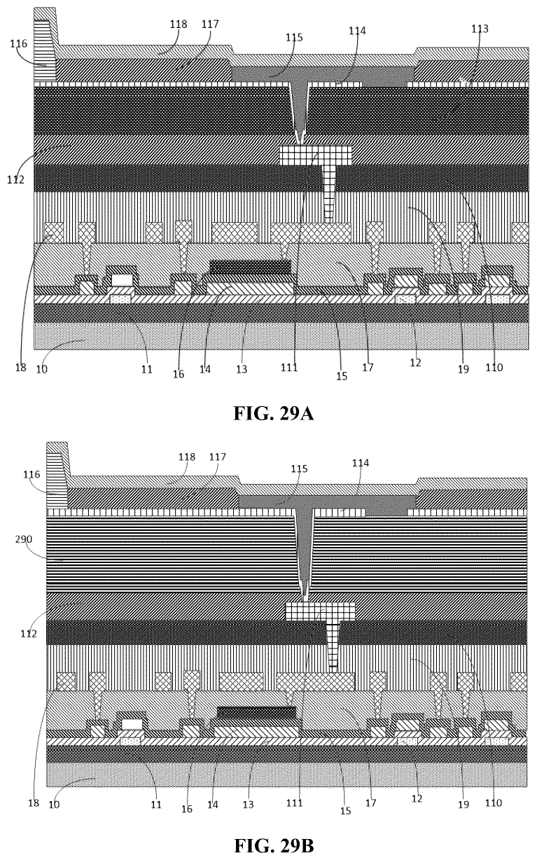

FIG. 29A is a cross-sectional view after a semiconductor layer, a first gate metal layer, a second gate metal layer, a first source-drain metal layer, a second source-drain metal layer, a first ITO layer, a first pixel defining layer, a second pixel defining layer, a light emitting layer and a cathode layer are arranged on a base substrate, in which a connecting via hole is shown between the electrode plate of the storage capacitor located in the second gate metal layer and the anode of the light emitting element located in the first ITO layer.

In FIGS. 29A, 10 is the base substrate, 11 is the second insulating layer, 12 is the semiconductor layer, 13 is the first gate insulating layer, 14 is the first gate metal layer, 15 is the second gate insulating layer, 16 is the second gate metal layer, 17 is the interlayer dielectric layer, 18 is the first source and drain metal layer, 19 is the first planarization layer, 110 is the first passivation layer, 111 is the second source-drain metal layer, 112 is the second passivation layer, 113 is the second planarization layer, 114 is the first ITO layer, 115 is the first pixel defining layer, 116 is the second pixel defining layer, 117 is the light emitting layer, and 118 is the cathode layer.

As shown in FIG. 29A, the via holes of the first planarization layer 19 and the via holes of the second planarization layer 113 avoid the pixel opening area.

The difference between FIG. 29B and FIG. 29A is that: an anode planarization layer 290 is provided between the second source-drain metal layer 111 and the first ITO layer 114;

The thickness of the anode planarization layer 290 is greater than the thickness of the second planarization layer;

The via holes of the anode planarization layer 290 can avoid the pixel opening area.

The display device described in the embodiment of the present disclosure includes the above-mentioned display panel.

Optionally, the display panel includes a sub-pixel;

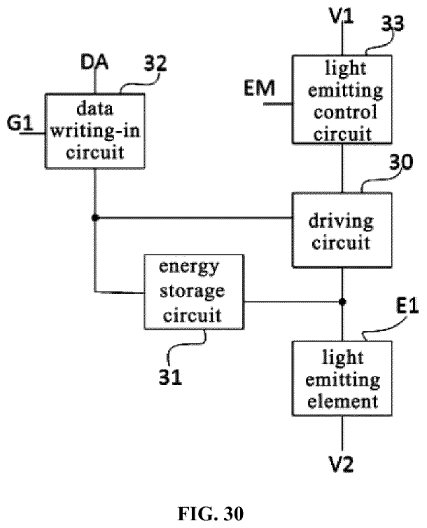

As shown in FIG. 30, the sub-pixel includes a light emitting element E1, an energy storage circuit 31, a driving circuit 30, a data writing-in circuit 32 and a light emitting control circuit 33;

The first terminal of the energy storage circuit 31 is electrically connected to the anode of the light emitting element E1; the control terminal of the driving circuit 30 is electrically connected to the second terminal of the energy storage circuit 31, the first terminal of the driving circuit 30 is electrically connected to the anode of the light emitting element E1, and the cathode of the light emitting element E1 is electrically connected to the second voltage line V2;

The data writing-in circuit 32 is electrically connected to the first scanning line G1, the data line DA and the second terminal of the energy storage circuit 31 respectively, and is used to write the data voltage provided by the data line DA into the second terminal of the energy storage circuit 31 under the control of the first scanning signal provided by the first scanning line G1;

The light emitting control circuit 33 is electrically connected to the light emitting control line EM, the second terminal of the driving circuit 30 and the first voltage line V1 respectively, and is used to control to connect the first voltage line V1 and the second terminal of the driving circuit 30 under the control of the light emitting control signal provided by the light emitting control line EM.

Optionally, the first voltage line may be a high voltage line, and the second voltage line may be a low voltage line.

In at least one embodiment of the present disclosure, the light emitting element E1 may be an organic light emitting diode, but is not limited thereto. In actual operation, the light emitting element E1 may also be other types of light emitting diodes.

Optionally, the sub-pixel further includes a first reset circuit and a second reset circuit;

The second reset circuit is electrically connected to the second scanning line, the reference voltage line and the second terminal of the energy storage circuit, respectively, and is used to write the reference voltage provided by the reference voltage line into the second terminal of the energy storage circuit under the control of the second scanning signal provided by the second scanning line;

The first reset circuit is electrically connected to the third scanning line, the initial voltage line and the anode of the light emitting element, respectively, and is used to write the initial voltage provided by the initial voltage line into the anode of the light emitting element under the control of the third scanning signal provided by the third scanning line.

In specific implementation, the sub-pixel may further include a first reset circuit and a second reset circuit, the first reset circuit is used to reset the potential of the second terminal of the energy storage circuit, and the first reset circuit is used to reset the potential of the anode of the light emitting element.

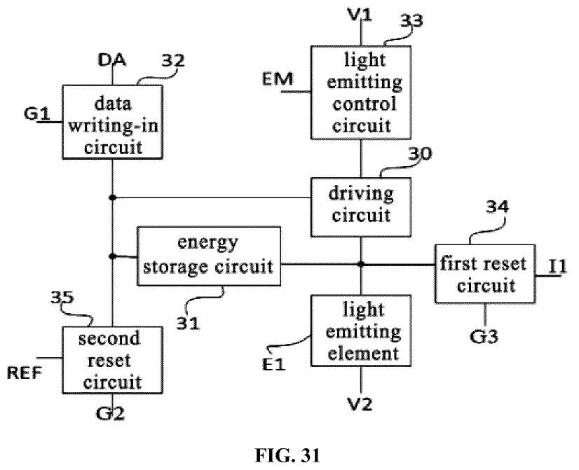

As shown in FIG. 31, based on at least one embodiment of the sub-pixel shown in FIG. 30, the sub-pixel may further include a first reset circuit 34 and a second reset circuit 35;

The second reset circuit 35 is electrically connected to the second scanning line G2, the reference voltage line REF and the second terminal of the energy storage circuit 31 respectively, and is used to write the reference voltage Vfef provided by the reference voltage line REF into the second terminal of the energy storage circuit 31 under the control of the second scanning signal provided by the second scanning line G2;

The first reset circuit 34 is electrically connected to the third scanning line G3, the initial voltage line I1 and the anode of the light emitting element E1 respectively, and is used to write the initial voltage Vi provided by the initial voltage line I1 into the anode of the light emitting element E1 under the control of the third scanning signal provided by the third scanning line G3.

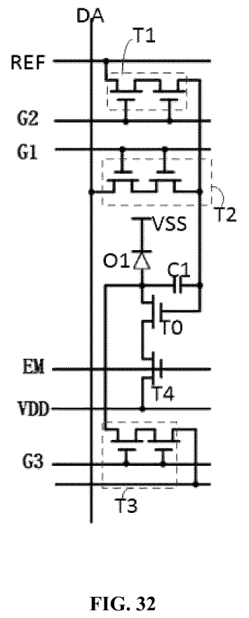

As shown in FIG. 32, based on at least one embodiment of the sub-pixel shown in FIG. 31, the light emitting element may be an organic light emitting diode O1, the energy storage circuit includes a storage capacitor C1, the first reset circuit includes a first reset transistor T3, the data writing-in circuit may include a data writing-in transistor T2, the second reset circuit may include a second reset transistor T1, the driving circuit may include a driving transistor T0, and the light emitting control circuit may include a light emitting control transistor T4;

The gate electrode of the first reset transistor T3 is electrically connected to the third scanning line G3, the first electrode of the first reset transistor T3 is electrically connected to the anode of the organic light emitting diode O1, and the second electrode of the first reset transistor T3 is electrically connected to the initial voltage line I1; the cathode of O1 is electrically connected to the low voltage line VSS;

The anode of the organic light emitting diode O1 is electrically connected to the first electrode plate of the storage capacitor C1; the second electrode plate of the storage capacitor C1 is electrically connected to the second electrode of the data writing-in transistor T2;

The gate electrode of the data writing-in transistor T2 is electrically connected to the first scanning line G1, and the first electrode of the data writing-in transistor T2 is electrically connected to the first column data line DA1;

The gate electrode of the second reset transistor T1 is electrically connected to the second scanning line G2, the first electrode of the second reset transistor T1 is electrically connected to the reference voltage line REF, and the second electrode of the second reset transistor T1 is electrically connected to the second electrode of the data writing-in transistor T2;

The gate electrode of the driving transistor T0 is electrically connected to the second electrode plate of the storage capacitor, the first electrode of the driving transistor T0 is electrically connected to the anode of the organic light emitting diode O1, and the second electrode of the driving transistor T0 is electrically connected to the first electrode of the light emitting control transistor T4;

The gate electrode of the light emitting control transistor T4 is electrically connected to the light emitting control line EM, and the second voltage of the light emitting control transistor T4 is electrically connected to the high voltage line VDD.

In at least one embodiment of the sub-pixel shown in FIG. 32, all transistors are n-type transistors.

In at least one embodiment of the present disclosure, the display panel may include the plurality rows and the plurality columns of sub-pixels shown in FIG. 32;

When the display panel is in operation, two rows of sub-pixels can be reset and compensated at the same time, and then two rows of sub-pixels can be light emitted after writing-in data voltages row by row.

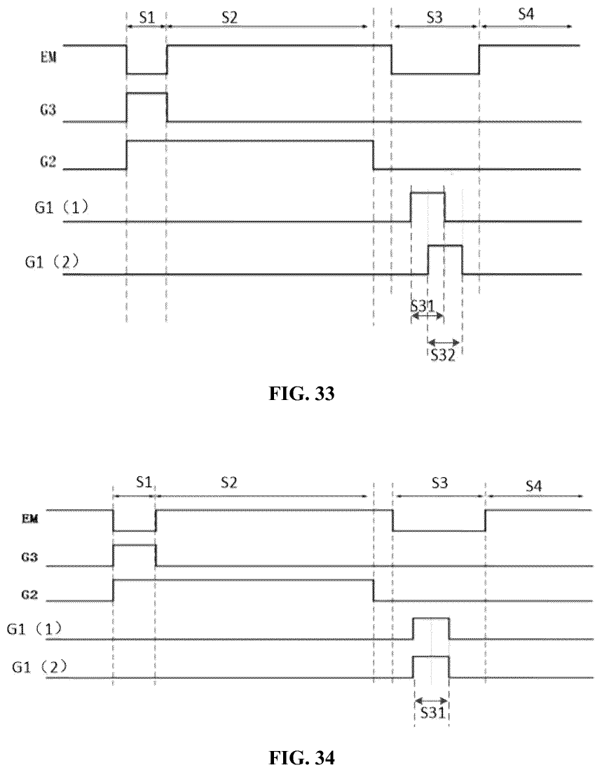

As shown in FIG. 33, when at least one embodiment of the display panel is in operation, the display period may include a reset phase S1, a compensation phase S2, a data writing-in phase S3, and a light emitting phase S4 that are successively set;

In the reset phase S1, G3 provides a high voltage signal, T3 is turned on, so as to write Vi into the anode of O1 and clear the residual charge on the anode of O1; G2 provides a high voltage signal, T1 is turned on, so as to write Vref into the second electrode of the data writing-in transistor T2;

In the compensation phase S2, G2 provides a high voltage signal, EM provides a high voltage signal, T1 is turned on, and T4 is turned on;

In the data writing-in phase S3, G1(1) and G2(2) successively output high voltage signals, T2 in the first row of sub-pixels and T2 in the second row of sub-pixels are successively turned on, and the corresponding data voltages are successively written into the corresponding sub-pixels; wherein, G1(1) is the first scanning line of the first row electrically connected to the first row of sub-pixels, and G1(2) is the first scanning line of the second row electrically connected to the second row of sub-pixels;

As shown in FIG. 33, in the data writing-in phase S23, the time period when G1(1) outputs a high voltage signal partially overlaps the time period when G1(2) outputs a high voltage signal, which is easier to be compatible with large-size loads;

In the light emitting phase S4, EM provides a high voltage signal, and T0 drives O1 to emit light.

In FIG. 33, the first writing-in time phase is labeled S31, and the second writing-in time phase is labeled S32.

FIG. 34 is a timing of doubling resolution refresh frequency when pixel combination. In FIG. 34, the reset and compensation timings are the same as FIG. 33;

As shown in FIG. 34, the first writing-in time period S31 and the second writing-in time period are the same time period. In the first writing-in time period S31, the first row of sub-pixels and the second sub-pixels write the same data, realizing a display with reduced resolution and doubled refresh rate.

The driving method described in the embodiment of the present disclosure is applied to the above-mentioned display device, and the display period includes N display phases; the nth display phase includes the nth data writing-in phase set in sequence; N is an integer greater than 1, and n is a positive integer less than or equal to N; the driving method includes: in at least part of the time period included in the nth data writing-in phase, the data writing-in circuit included in the (2n-1)th row of sub-pixels writing the data voltage to the second terminal of the energy storage circuit included in the (2n-1)th row of sub-pixels under the control of the first scanning signal provided by the first scanning line of the (2n-1)th row, and the data writing-in circuit included in the 2nth row of sub-pixels writing the data voltage to the second terminal of the energy storage circuit included in the 2nth row of sub-pixels under the control of the first scanning signal provided by the first scanning line of the 2nth row.

In at least one embodiment of the present disclosure, the nth data writing-in phase includes an nth first writing-in time period and an nth second writing-in time period;

The driving method includes:

In the nth first writing-in time period, writing, by the data writing-in circuit included in the (2n-1)th row of sub-pixels, the data voltage into the second terminal of the energy storage circuit included in the (2n-1)th row of sub-pixels under the control of the first scanning signal provided by the first scanning line of the (2n-1)th row;

In the nth second writing-in time period, writing, by the data writing-in circuit included in the 2nth row of sub-pixels, the data voltage to the second terminal of the energy storage circuit included in the 2nth row of sub-pixels under the control of the first scanning signal provided by the first scanning line of the 2nth row;

The nth first writing-in time period and the nth second writing-in time period overlap at least partially.

The above descriptions are implementations of the present disclosure. It should be pointed out that those skilled in the art can make some improvements and modifications without departing from the principle of the present disclosure. These improvements and modifications shall also fall within the scope of the present disclosure.

1. A display panel, comprising a base substrate, a plurality of pixel opening areas arranged on the base substrate, at least one planarization layer and at least two conductive layers stacked on the base substrate, wherein one planarization layer is arranged between adjacent conductive layers, and the planarization layer has a first type of via hole and a second type of via hole;
the display panel includes a signal line for transmitting a reference voltage signal, and a signal line for transmitting a power supply voltage signal;
the signal line for transmitting the reference voltage signal includes a first signal line and a second signal line; the first signal line is electrically connected to the second signal line through the first type of via hole;
the signal line for transmitting the power supply voltage signal includes a third signal line and a fourth signal line, and the third signal line is electrically connected to the fourth signal line through the second type of via hole;
an orthographic projection of the first type of via hole on the base substrate does not overlap an orthographic projection of the pixel opening area on the base substrate;
an orthographic projection of the second type of via hole on the base substrate does not overlap the orthographic projection of the pixel opening area on the base substrate.

2. The display panel according to claim 1, wherein the display panel comprises a first conductive layer, a second conductive layer, and a first planarization layer; the first conductive layer, the first planarization layer, and the second conductive layer are arranged in sequence along a direction away from the base substrate; the first signal line is a first reference signal line, and the second signal line is a first reference connection line; the first type of via hole includes a first via hole;
the first conductive layer includes the first reference signal line, and the second conductive layer includes the first reference connection line;
the first planarization layer has the first via hole; the first reference signal line is electrically connected to the first reference connection line through the first via hole.

3. The display panel according to claim 2, wherein the display panel further comprises a third conductive layer; the first conductive layer includes a second reference signal line; the third conductive layer includes a second reference connection line; the second reference signal line is electrically connected to the second reference connection line;
the third conductive layer is provided between the base substrate and the first conductive layer;
the first reference connection line and the second reference connection line both extend along a first direction;
orthographic projections of two second reference connection lines on the base substrate are arranged on opposite sides of an orthographic projection of the first reference connection line on the base substrate.

4. The display panel according to claim 1, wherein the display panel comprises a first conductive layer, a second conductive layer, and a first planarization layer; the first conductive layer, the first planarization layer and the second conductive layer are arranged in sequence along a direction away from the base substrate; the third signal line is a first voltage line, and the fourth signal line is a first voltage connection line; the second type of via hole includes a second via hole;
the first conductive layer includes the first voltage line, and the second conductive layer includes the first voltage connection line;
the first planarization layer has the second via hole; the first voltage line is electrically connected to the first voltage connection line through the second via hole.

5. The display panel according to claim 1, wherein the planarization layer has a third type of via hole;
the display panel includes a plurality of sub-pixels arranged on the base substrate; the sub-pixels include a light emitting element, a storage capacitor, and a plurality of transistors;
the sub-pixel includes a plurality of conductive portions, the plurality of conductive portions include an anode of the light emitting element, electrode plates of the storage capacitor, and an electrode of the transistor;
some of the plurality of conductive portions are electrically connected through the third type of via hole;
an orthographic projection of the third type of via hole on the base substrate does not overlap the orthographic projection of the pixel opening area on the base substrate.

6. The display panel according to claim 1, wherein the planarization layer has a fourth type of via hole;
the display panel includes a plurality of data lines and a plurality of sub-pixels arranged on the base substrate;
some electrodes of some transistors in the sub-pixels are electrically connected to the data lines through the fourth type of via hole;
an orthographic projection of the fourth type of via hole on the base substrate does not overlap the orthographic projection of the pixel opening area on the base substrate.

7. The display panel according to claim 5, wherein the transistor in the sub-pixel comprises a first reset transistor; the third type of via hole comprises a third via hole and a fourth via hole;
the display panel also includes a semiconductor layer, a first conductive layer, a first planarization layer, a second conductive layer, a second planarization layer and a fourth conductive layer arranged in sequence in a direction away from the base substrate; the semiconductor layer includes a first electrode of the first reset transistor, and the fourth conductive layer includes an anode of the light emitting element; the first planarization layer has the third via hole, and the second planarization layer has the fourth via hole;
the first electrode of the first reset transistor is electrically connected to the anode of the light emitting element through the third via hole and the fourth via hole;
or
wherein the third type of via holes includes a fifth via hole and a sixth via hole;
the display panel further includes a fifth conductive layer, a first insulating layer, a first conductive layer, a first planarization layer, a second conductive layer, a second planarization layer and a fourth conductive layer arranged in sequence along a direction away from the base substrate;
the fourth conductive layer includes the anode of the light emitting element; the fifth conductive layer includes the first electrode plate of the storage capacitor;
the first planarization layer has the fifth via hole, and the second planarization layer has the sixth via hole:
the anode of the light emitting element is electrically connected to the first electrode plate of the storage capacitor through the sixth via hole, the fifth via hole, and a via hole penetrating the first insulating layer.

8. (canceled)

9. The display panel according to claim 6, wherein the transistor in the sub-pixel includes a data writing-in transistor; the fourth type of via hole includes a seventh via;
the display panel further includes a semiconductor layer, a first conductive layer, a first planarization layer, and a second conductive layer arranged in sequence along a direction away from the base substrate;
the semiconductor layer includes the first electrode of the data writing-in transistor, and the second conductive layer includes the data line;
the first planarization layer has the seventh via hole, and the first electrode of the data writing-in transistor is electrically connected to the data line through the seventh via hole.

10. The display panel according to claim 5, wherein the transistor in the sub-pixel includes a first reset transistor; the third type of via hole includes a third via hole, a fourth via hole and an eighth via hole;
the display panel further includes a semiconductor layer, a first conductive layer, a first planarization layer, a second conductive layer, a second planarization layer, a fourth conductive layer, a third planarization layer and a sixth conductive layer arranged in sequence in a direction away from the base substrate;
the semiconductor layer includes the first electrode of the first reset transistor, and the sixth conductive layer includes the anode of the light emitting element; the first planarization layer has the third via hole, the second planarization layer has the fourth via hole, and the third planarization layer has the eighth via hole;
the first electrode of the first reset transistor is electrically connected to the anode of the light emitting element through the third via hole, the fourth via hole and the eighth via hole;
or
wherein the third type of via holes includes a fifth via hole, a sixth via hole and a ninth via hole;
the display panel further includes a fifth conductive layer, a first insulating layer, a first conductive layer, a first planarization layer, a second conductive layer, a second planarization layer, a fourth conductive layer, a third planarization layer and a sixth conductive layer arranged in sequence in a direction away from the base substrate;
the sixth conductive layer includes the anode of the light emitting element, and the fifth conductive layer includes the first electrode plate of the storage capacitor;
the first planarization layer has the fifth via hole, the second planarization layer has the sixth via hole, and the third planarization layer has the ninth via hole;
the anode of the light emitting element is electrically connected to the first electrode plate of the storage capacitor through the ninth via hole, the sixth via hole, the fifth via hole, and the via hole penetrating the first insulating layer.

11. (canceled)

12. The display panel according to claim 3, wherein the plurality of sub-pixels are divided into a plurality of pixel units arranged in an array; the pixel unit includes a plurality of sub-pixels arranged along a second direction; the first direction intersects the second direction;
N columns of the pixel units are arranged between two adjacent columns of the first reference connection lines; N is an integer greater than 1;
wherein the display panel further includes a plurality of rows and a plurality of columns of lens group arranged on a side of the pixel unit away from the base substrate; the lens group includes an odd numbered lenses;
N pixel units located in a same row and arranged between two adjacent columns of first reference connection lines correspond to a same lens group;
wherein a pixel unit arranged between different two adjacent columns of first reference connection lines correspond to different lens groups;
or
wherein the second reference connection line is adjacent to the first reference connection line in the second direction.

13.-15. (canceled)

16. The display panel according to claim 1, wherein the display panel includes a plurality of sub-pixels arranged on the base substrate; the sub-pixel includes a light emitting element;
the display panel includes a second conductive layer, an anode planarization layer and a fourth conductive layer stacked in a direction away from the base substrate; the fourth conductive layer includes the anode of the light-emitting element;
a thickness of the anode planarization layer is greater than a thickness of the planarization layer;
wherein the sub-pixels further comprise a plurality of transistors and a storage capacitor;
the anode of the light emitting element is electrically connected to a part of electrodes of a part of the transistors in the plurality of transistors and/or a part of electrode plates of the storage capacitor through a fifth type of via hole in the anode planarization layer;
an orthographic projection of the fifth type of via hole on the base substrate does not overlap the orthographic projection of the pixel opening area on the base substrate.

17. (canceled)

18. The display panel according to claim 1, wherein the display panel comprises a plurality of sub-pixels arranged on the base substrate; the sub-pixel comprises a light emitting element; the light emitting element comprises a light emitting layer;
the light emitting layers of the light emitting elements in a same column of sub-pixels are continuous with each other and have a same color.

19. The display panel according to claim 1, wherein a thickness of the planarization layer is greater than a first thickness threshold, and the first thickness threshold is greater than or equal to 2.8 μm and less than or equal to 3.2 μm.

20. The display panel according to claim 1, wherein the display panel comprises a plurality of sub-pixels arranged on the base substrate; the sub-pixel comprises a light emitting element, a storage capacitor, a first reset transistor, a data writing-in transistor and a second reset transistor;
an active pattern of the second reset transistor is electrically connected to an active pattern of the data writing-in transistor through a first connection line; the active pattern of the data writing-in transistor is electrically connected to the second electrode plate of the storage capacitor through a second connection line;
the anode of the light emitting element is electrically connected to the active pattern of the first reset transistor through a third connection line;
the first connection line, the second connection line and the third connection line are arranged on a same layer as the active pattern.

21. The display panel according to claim 1, wherein the display panel comprises a first pixel defining layer and a second pixel defining layer;
the second pixel defining layer forms a plurality of openings arranged along the second direction, and the openings extend along the first direction;
the first pixel defining layer comprises a plurality of pixel defining portions arranged along the first direction, the pixel defining portions fill a part of the openings, and the plurality of pixel defining portions define a plurality of pixel opening areas in the plurality of openings.

22. The display panel according to claim 19, wherein the pixel defining portion comprises an integral structure extending along the second direction; or,
the pixel defining portion comprises a plurality of pixel defining patterns arranged along the second direction, and at least a part of the pixel defining patterns fills in a corresponding opening;
or
wherein a maximum distance between the first pixel defining layer and the base substrate is different from a maximum distance between the second pixel defining layer and the base substrate.

23. (canceled)

24. A display device comprising a display panel according to claim 1.

25. The display device according to claim 24, wherein the display panel includes a sub-pixel;
the sub-pixel includes a light emitting element, an energy storage circuit, a driving circuit, a data writing-in circuit and a light emitting control circuit;
a first terminal of the energy storage circuit is electrically connected to an anode of the light emitting element; a control terminal of the driving circuit is electrically connected to a second terminal of the energy storage circuit, a first terminal of the driving circuit is electrically connected to the anode of the light emitting element, and a cathode of the light emitting element is electrically connected to the second voltage line;
the data writing-in circuit is electrically connected to a first scanning line, a data line and the second terminal of the energy storage circuit respectively, and is configured to write a data voltage provided by the data line into the second terminal of the energy storage circuit under the control of a first scanning signal provided by the first scanning line;
the light emitting control circuit is electrically connected to the light emitting control line, a second terminal of the driving circuit and the first voltage line respectively, and is configured to control to connect the first voltage line and the second terminal of the driving circuit under the control of a light emitting control signal provided by the light emitting control line:
or
wherein the sub-pixel further comprises a first reset circuit and a second reset circuit;
the second reset circuit is electrically connected to a second scanning line, a reference voltage line and a second terminal of the energy storage circuit, respectively, and is configured to write a reference voltage provided by the reference voltage line into the second terminal of the energy storage circuit under the control of a second scanning signal provided by the second scanning line;
the first reset circuit is electrically connected to a third scanning line, an initial voltage line and the anode of the light emitting element, respectively, and is configured to write an initial voltage provided by the initial voltage line into the anode of the light emitting element under the control of a third scanning signal provided by the third scanning line.

26. (canceled)

27. A driving method, applied to the display device according to claim 25, wherein a display period includes N display phases; an nth display phase includes an nth data writing-in phase set in sequence; N is an integer greater than 1, and n is a positive integer less than or equal to N; the driving method includes: in at least part of the time period included in the nth data writing-in phase, writing, by the data writing-in circuit included in an (2n-1)th row of sub-pixels, the data voltage into a second terminal of an energy storage circuit included in the (2n-1)th row of sub-pixels under the control of the first scanning signal provided by the first scanning line of the (2n-1)th row, and writing, by the data writing-in circuit included in the 2nth row of sub-pixels, the data voltage into a second terminal of an energy storage circuit included in the 2nth row of sub-pixels under the control of the first scanning signal provided by the first scanning line of the 2nth row.

28. The driving method according to claim 27, wherein the nth data writing-in phase includes an nth first writing-in time period and an nth second writing-in time period;
the driving method includes:
in the nth first writing-in time period, writing, by the data writing-in circuit included in the (2n-1)th row of sub-pixels, the data voltage into the second terminal of the energy storage circuit included in the (2n-1)th row of sub-pixels under the control of the first scanning signal provided by the first scanning line of the (2n-1)th row;
in the nth second writing-in time period, writing, by the data writing-in circuit included in the 2nth row of sub-pixels, the data voltage into the second terminal of the energy storage circuit included in the 2nth row of sub-pixels under the control of the first scanning signal provided by the first scanning line of the 2nth row;
wherein the nth first writing-in time period and the nth second writing-in time period overlap at least partially.
